(19) United States
(12) Patent Application Publication
(10) Pub. No.: US 2026/0259462 A1
(43) Pub. Date: Sep. 3, 2026

(54) DISPLAY PANEL AND DISPLAY DEVICE

(71) Applicant: Xiamen Tianma Micro-Electronics Co., Ltd., Xiamen (CN)

(72) Inventors: Xiaofen CHEN, Xiamen (CN); Ling WU, Xiamen (CN); Liting FANG, Xiamen (CN); Chuhui FENG, Xiamen (CN); Minzheng HUANG, Xiamen (CN); Xiaohe LI, Xiamen (CN)

(21) Appl. No.: 19/191,872

(22) Filed: Apr. 28, 2025

(30) Foreign Application Priority Data
Feb. 28, 2025 (CN) 202510234322.0

(51) Int. Cl. G02F 1/1368; G02F 1/1362; H10D 86/40

(52) U.S. Cl. CPC G02F 1/1368; G02F 1/136209; G02F 1/136286; H10D 86/441

(57) ABSTRACT

A display panel and a display device are provided. An array substrate of the display panel includes a first substrate, a semiconductor layer, a first metal layer and a second metal layer. The sub-pixel of the display panel includes a thin-film transistor and a pixel electrode. The active part of the thin-film transistor is electrically connected to its first terminal through a first via hole, and the first terminal is electrically connected to a data line. The third metal layer between the first substrate and the semiconductor layer includes first light-shielding members. At the first via hole, the orthographic projection of the first via hole on the first substrate (a first projection) is at least located within the orthographic projection range of the first light-shielding member on the first substrate (a second projection), and the edge of the second projection half surrounds the edge of the first projection.

### CROSS-REFERENCE TO RELATED APPLICATION

This application claims the priority of Chinese Patent Application No. 202510234322.0, filed on February 28, 2025, the content of which is incorporated by reference in its entirety.

### TECHNICAL FIELD

The present disclosure generally relates to the field of display technologies and, more particularly, relates to a display panel and a display device.

### BACKGROUND

Liquid crystal display (LCD) has been increasingly widely used in the display field due to its advantages of low power-consumption, miniaturization, and thinness. With the development of human-computer interaction technologies, display devices with touch functions have been favored by consumers, such as mobile phones, tablet computers, and laptops with touch functions. In the LCD display devices, thin-film transistors (TFT) are generally used as switch devices in pixel units to control the on and off of pixel electrodes. The source and drain in the TFT are connected through via holes, but the metal material layer at the via hole position will leak light due to metal diffraction, scattering, and other reasons. In particular, with the increasing maturity of technologies such as in-vehicle displays, customers' specifications for contrast are becoming more and more stringent. Improving contrast requires increasing light- state brightness or reducing dark-state brightness.

The existing technologies cannot take into account both the high transmittance and high contrast requirements. If the panel design compresses the device and the light-shielding black matrix to increase the aperture ratio, once the alignment ability of the color filter substrate and the array substrate is poor, it is easy to shift, resulting in the metal on the array substrate side being exposed in the opening area defined by the black matrix on the color filter substrate. The black matrix layer cannot completely block the metal light leakage at the via hole, resulting in metal light leakage, and the dark state light leakage is serious, so the contrast cannot meet the high requirements of customers. If the light-shielding area of the black matrix is increased to improve the contrast, that is, the metal light leakage phenomenon is improved by sacrificing the aperture ratio, the transmittance of the display device will be affected.

Therefore, providing a display panel and a display device that can compress the light-shielding black matrix area as much as possible to achieve the high transmittance while effectively reducing the dark-state light leakage and improving the product contrast is a technical problem that needs to be solved by those skilled in the art. The present disclosed display panels and display devices are direct to solve the above problems, and other problems in the arts.

### SUMMARY

One aspect of the present disclosure provides a display panel. The display panel includes an array substrate and a counter substrate arranged oppositely; a plurality of sub-pixels; a plurality of scan lines; and a plurality of data lines. The array substrate includes a first substrate, and a semiconductor layer, a first metal layer and a second metal layer located on a side of the first substrate facing the counter substrate. The plurality of scan lines and the plurality of data lines are cross-insulated to define area where the plurality of sub-pixels are located. A sub-pixel of the plurality of sub-pixels includes a thin-film transistor and a pixel electrode that are electrically connected, the plurality of scan lines are located in the first metal layer, an active part of the thin-film transistor is located in the semiconductor layer, and a first terminal and a second terminal of the thin-film transistor and the plurality of data lines are located in the second metal layer. The active part of the thin-film transistor is electrically connected to the first terminal of the thin-film transistor through a first via hole, the first terminal of the thin-film transistor is electrically connected to a data line of the plurality of data lines, and the second terminal of the thin-film transistor is electrically connected to the pixel electrode. A third metal layer is also included between the first substrate and the semiconductor layer, the third metal layer includes a plurality of first light-shielding members and, at the first via hole, an orthographic projection of the first via hole on the first substrate is at least within an orthographic projection range of a first light-shielding member of the plurality of light-shielding member on the first substrate. The orthographic projection of the first via hole on the first substrate is a first projection, the orthographic projection of the first light-shielding member on the first substrate is a second projection, and an edge of the second projection half surrounds an edge of the first projection.

Another aspect of the present disclosure provides a display device. The display device includes a display panel. The display panel includes an array substrate and a counter substrate arranged oppositely; a plurality of sub-pixels; a plurality of scan lines; and a plurality of data lines. The array substrate includes a first substrate, and a semiconductor layer, a first metal layer and a second metal layer located on a side of the first substrate facing the counter substrate. The plurality of scan lines and the plurality of data lines are cross-insulated to define area where the plurality of sub-pixels are located. A sub-pixel of the plurality of sub-pixels includes a thin-film transistor and a pixel electrode that are electrically connected, the plurality of scan lines are located in the first metal layer, an active part of the thin-film transistor is located in the semiconductor layer, and a first terminal and a second terminal of the thin-film transistor and the plurality of data lines are located in the second metal layer. The active part of the thin- film transistor is electrically connected to the first terminal of the thin-film transistor through a first via hole, the first terminal of the thin-film transistor is electrically connected to a data line of the plurality of data lines, and the second terminal of the thin-film transistor is electrically connected to the pixel electrode. A third metal layer is also included between the first substrate and the semiconductor layer, the third metal layer includes a plurality of first light-shielding members and, at the first via hole, an orthographic projection of the first via hole on the first substrate is at least within an orthographic projection range of a first light-shielding member of the plurality of light-shielding member on the first substrate. The orthographic projection of the first via hole on the first substrate is a first projection, the orthographic projection of the first light-shielding member on the first substrate is a second projection, and an edge of the second projection half surrounds an edge of the first projection.

Other aspects of the present disclosure can be understood by those skilled in the art in light of the description, the claims, and the drawings of the present disclosure.

### BRIEF DESCRIPTION OF THE DRAWINGS

To illustrate the technical solutions in the embodiments of the present disclosure more clearly, the following briefly introduces the accompanying drawings used in the description of the embodiments. Obviously, the accompanying drawings in the following description are only some embodiments of the present disclosure, for those of ordinary skill in the art, other drawings can also be obtained from these drawings without creative effort.

FIG. 1 illustrates an exemplary display panel according to various embodiments of the present disclosure;

FIG. 2 illustrates an exemplary partially zoomed-in view of J1 area in FIG. 1;

FIG. 3 illustrates an exemplary partially zoomed-in view of J2 area in FIG. 2;

FIG. 4 illustrates an A-A'-sectional view in FIG. 2;

FIG. 5 illustrates a B-B'-sectional view in FIG. 2;

FIG. 6 illustrates a simulation result after increasing light-shielding area of the black matrix layer disposed on the counter substrate;

FIG. 7 illustrates an exemplary simulation result after increasing light-shielding area of the black matrix layer disposed on the counter substrate;

FIG. 8 illustrates an exemplary orthographic projection of the first via hole and the first light-shielding member on the first substrate in FIG. 2 and FIG. 3;

FIG. 9 illustrates another exemplary orthographic projection of the first via hole and the first light-shielding member on the first substrate in FIG. 2 and FIG. 3;

FIG. 10 illustrates another exemplary orthographic projection of the first via hole and the first light-shielding member on the first substrate in FIG. 2 and FIG. 3;

FIG. 11 illustrates another exemplary orthographic projection of the first via hole and the first light-shielding member on the first substrate in FIG. 2 and FIG. 3;

FIG. 12 illustrates another exemplary orthographic projection of the first via hole and the first light-shielding member on the first substrate in FIG. 2 and FIG. 3;

FIG. 13 illustrates another exemplary orthographic projection of the first via hole and the first light-shielding member on the first substrate in FIG. 2 and FIG. 3;

FIG. 14 illustrates another exemplary partially zoomed-in view of J2 area in FIG. 2;

FIG. 15 illustrates another exemplary partially zoomed-in view of J2 area in FIG. 2;

FIG. 16 illustrates another exemplary partially zoomed-in view of J2 area in FIG. 2;

FIG. 17 illustrates another exemplary partially zoomed-in view of J2 area in FIG. 2;

FIG. 18 illustrates another exemplary partially zoomed-in view of J1 area in FIG. 1;

FIG. 19 illustrates an exemplary C-C' sectional view in FIG. 18;

FIG. 20 illustrates another exemplary partially zoomed-in view of J1 area in FIG. 1;

FIG. 21 illustrates another exemplary partially zoomed-in view of J3 area in FIG. 20;

FIG. 22 illustrates an exemplary D-D'-sectional view in FIG. 20;

FIG. 23 illustrates an exemplary D-D'-sectional view in FIG. 20;

FIG. 24 illustrates another exemplary orthographic projection of the first via hole and the first light-shielding member and the second via hole and the second light-shielding layer on the first substrate in FIG. 20;

FIG. 25 illustrates another exemplary partially zoomed-in view of J1 area in FIG. 1;

FIG. 26 illustrates an exemplary F-F'-sectional view in FIG. 25;

FIG. 27 illustrates another exemplary C-C'-sectional view in FIG. 18;

FIG. 28 illustrates another exemplary F-F'-sectional view in FIG. 25;

FIG. 29 illustrates a simulation result of a product under the dark state;

FIG. 30 illustrates another simulation result of product under the dark state;

FIG. 31 illustrates another exemplary partially zoomed-in view of J1 area in FIG. 1;

FIG. 32 illustrates another exemplary partially zoomed-in view of Ji area in FIG. 1; and

FIG. 33 illustrates an exemplary display device according to various embodiments of the present disclosure.

### DETAILED DESCRIPTION

To more clearly understand the above-mentioned purposes, features and advantages of the present disclosure, the scheme of the present disclosure will be further described below. It should be noted that the embodiments of the present disclosure and the features in the embodiments can be combined with each other without conflict.

In the following description, many specific details are explained to facilitate a full understanding of the present disclosure, but the present disclosure can also be implemented in other ways different from those described herein; obviously, the embodiments in the specification are only part of the embodiments of the present disclosure, not all of them.

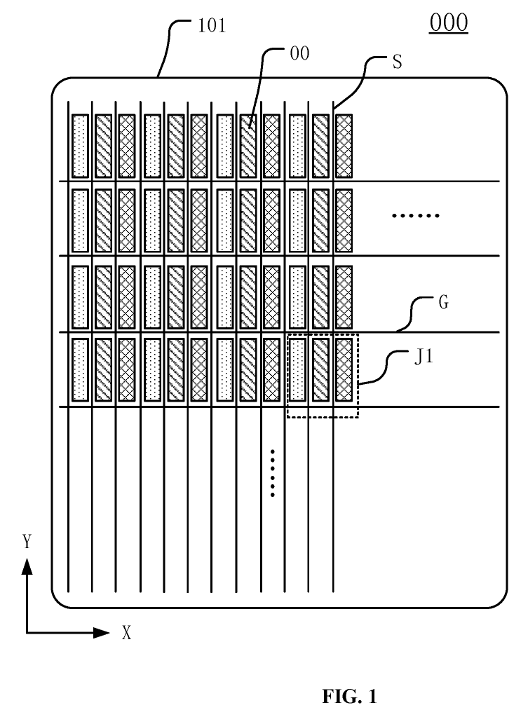

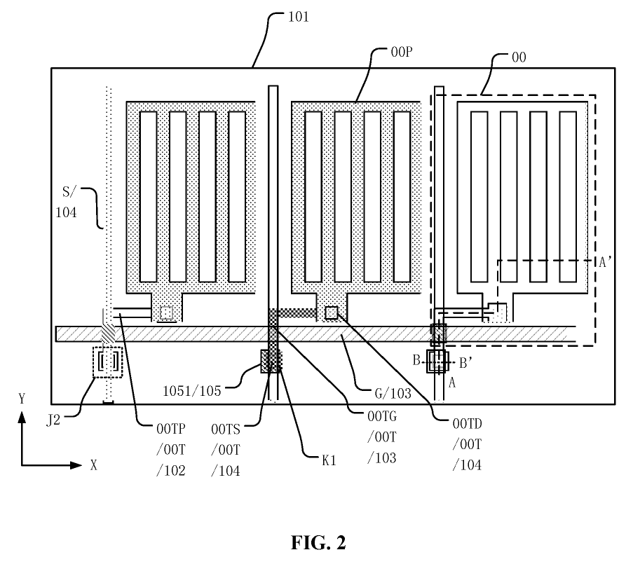

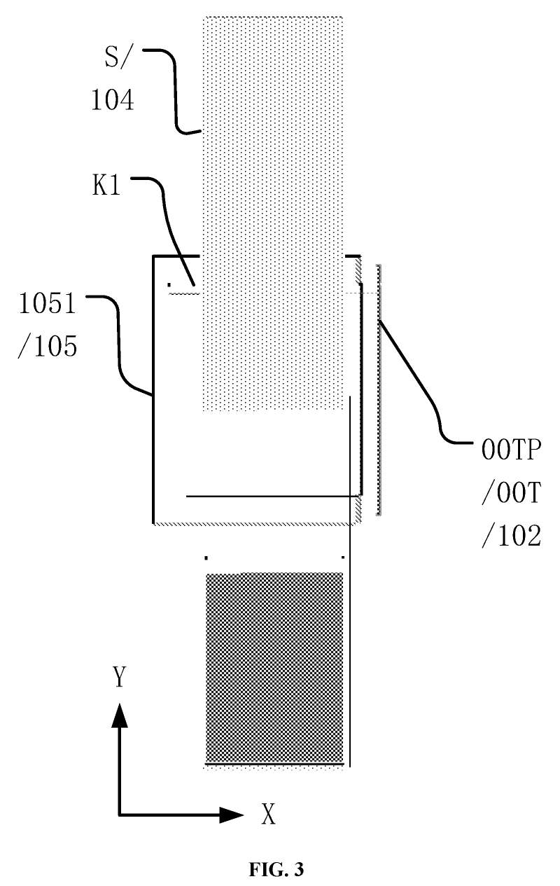

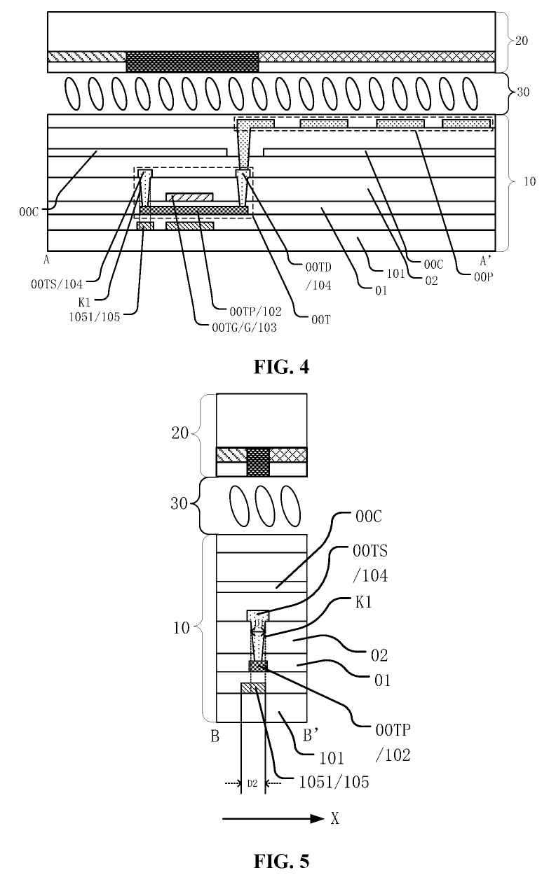

The present disclosure provides a display panel and a display device. FIG. 1 is a schematic diagram of a planar structure of an exemplary display panel provided by one embodiment of the present disclosure. FIG. 2 is a partially enlarged schematic diagram of the Ji region in FIG. 1. FIG. 3 is a partially enlarged schematic diagram of the J2 region in FIG. 2. FIG. 4 is a schematic diagram of a cross-sectional structure along the A-A' direction in FIG. 2. FIG. 5 is a schematic diagram of a cross-sectional structure along the B-B' direction in FIG. 2 (it can be understood that, to clearly illustrate the structure of this embodiment, FIGS. 2-3 are filled with transparency). As shown in FIGS. 1-5, a display panel 000 provided by one embodiment may include an array substrate 10 and a counter substrate 20 that are arranged oppositely. The array substrate 10 may include a first substrate 101, and a semiconductor layer 102, a first metal layer 103 and a second metal layer 104 located on the side of the first substrate 101 facing the counter substrate 20. The first substrate 101 is not filled in the figures.

The display panel 000 may include a plurality of sub-pixels 00, a plurality of scan lines G and a plurality of data lines S. The scan lines G and the data lines S may be cross- insulated to define the area where the sub-pixels 00 are located.

The sub-pixel 00 may include an electrically connected thin-film transistor 00T and a pixel electrode 00P. The scan line G may be located in the first metal layer 103. The active part 00TP of the thin-film transistor 00T may be located in the semiconductor layer 102. The first electrode 00TS and the second electrode 00TD of the thin-film transistor 00T and the data line S may be located in the second metal layer 104. The active part 00TP of the thin-film transistor 00T may be electrically connected to the first terminal 00TS of the thin-film transistor 00T through the first via Ki. The first terminal 00TS of the thin-film transistor 00T may be electrically connected to the data line S, and the second terminal 00TD of the thin-film transistor 00T may be electrically connected to the pixel electrode 00P.

A third metal layer 105 may also be included between the first substrate 101 and the semiconductor layer 102, and the third metal layer 105 may include a plurality of first light- shielding members 1051. At the first via hole K1, the orthographic projection of the first via hole K1 on the first substrate 101 may be at least located within the orthographic projection range of the first light-shielding member 1051 on the first substrate 101.

The orthographic projection of the first via hole K1 on the first substrate 101 may be the first projection, and the orthographic projection of the first light-shielding portion 1051 on the first substrate 101 may be the second projection. The edge of the second projection may half surround the edge of the first projection.

The display panel 000 provided in this embodiment may be a liquid crystal display panel. The display panel 000 may include the array substrate 10 and the counter substrate 20 that are arranged oppositely. The array substrate 10 may be a substrate that is provided with structures such as thin-film transistors, pixel electrodes, and common electrodes. The counter substrate 20 may be a substrate that is provided with color resist and a black matrix layer, and a liquid crystal layer 30 may be arranged between the array substrate 10 and the counter substrate 20 (as shown in FIG. 4). In some other embodiments, the color resist and the black matrix layer may also be arranged on one side of the array substrate 10, and the counter substrate 20 may be a glass cover structure. This embodiment does not limit the structure of the counter substrate 20. When it is implemented, it may be selected according to actual needs. This embodiment and subsequent embodiments are all described by taking the counter substrate 20 as a substrate for setting the color resist and the black matrix layer as an example.

As shown in FIG. 4, the array substrate 10 of this embodiment may include a first substrate 101 and a semiconductor layer 102, a first metal layer 103 and a second metal layer 104 located on the side of the first substrate 101 facing the counter substrate 20. The first substrate 101 may be used as a carrier substrate for setting other structures of the array substrate 10, and the first substrate 101 may be made of hard materials such as glass or ceramics, which is not limited in this embodiment. The display panel 000 may include a plurality of sub-pixels 00, a plurality of scan lines G and a plurality of data lines S. In one embodiment, as shown in FIG. 1, the display panel 000 may include the scan lines G extending along a first direction X as a whole and the data lines S extending along a second direction Y as a whole, and the two may be cross- insulated to define the area where the sub-pixel 00 is located. It can be understood that the scan lines G extending along the first direction X as a whole and the data lines S extending along the second direction Y as a whole may indicate that the scan lines G and the data lines S may be curved or bent lines, but the scan lines G extending in the first direction X as a whole and the data lines S extending in the second direction Y as a whole may be perpendicular to each other in a direction parallel to the plane where the first substrate 101 is located. The subsequent embodiments refer to the above explanations, and all take the scan lines G extending in the first direction X and the data lines S extending in the second direction Y as an example, and will not be described in detail.

The sub-pixel 00 may include an electrically connected thin-film transistor 00T and a pixel electrode 00P, and the thin-film transistor 00T may be used as a switch element of the sub-pixel 00. The semiconductor layer 102 of the array substrate 10 may be used to set the active part 00TP of the thin-film transistor 00T. The first metal layer 103 of the array substrate 10 may be located on the side of the semiconductor layer 102 away from the first substrate 101, and the first metal layer 103 may be used to set the scan line G, and the first metal layer 103 may also be used to set the gate 00TG of the thin-film transistor 00T. At least a part of the scan line G may be multiplexed as the gate 00TG of the thin-film transistor 00T (as shown in FIG. 4). It may be understood that, generally, the overlapping area between the gate and the active part of the thin-film transistor, that is, the channel area, may be provided with a light-shielding structure that matches the shape of the channel area (such as the light-shielding structure provided in the overlapping area between the gate 00TG and the active part 00TP of the thin-film transistor 00T in FIG. 3 ). The light-shielding structure (not labeled) may be used to block the backlight in the channel area. In the liquid crystal display device, a backlight module needs to be provided on the side of the first substrate 101 of the display panel 000 away from the counter substrate 20 to provide a backlight source, that is, to block the light from the backlight module to prevent the light from irradiating into the channel area of the thin-film transistor 00T, thereby reducing the photogenerated carriers of the active part 00TP of the thin-film transistor 00T, thereby reducing the light leakage current of the thin-film transistor 00T, improving the conductive performance of the thin-film transistor 00T, improving the display crosstalk phenomenon, and being beneficial to improving the display quality. The second metal layer 104 of the array substrate 10 may be located on the side of the first metal layer 103 away from the first substrate 101, and the second metal layer 104 may be used to set the first terminal 00TS and the second terminal 00TD of the thin-film transistor 00T, and the data line S may be located in the second metal layer 104. It can be understood that the first terminal 00TS of the thin-film transistor 00T may be one of the source or the drain, and the second terminal 00TD may be the other of the source or the drain. In this embodiment, the first terminal 00TS may used as the source of the thin-film transistor 00T, and the second terminal 00TD may be used as the drain of the thin-film transistor 00T. The active part 00TP of the thin-film transistor 00T (the source connection area of the active part 00TP) may be electrically connected to the first terminal 00TS of the thin-film transistor 00T through the first via K1, and the first terminal 00TS of the thin-film transistor 00T may be electrically connected to the data line S. The active part 00TP of the thin-film transistor 00T (the drain connection area of the active part 00TP) may also be electrically connected to the second terminal 00TD of the thin-film transistor 00T, and the second terminal 00TD of the thin-film transistor 00T may be electrically connected to the pixel electrode 00P. In this embodiment, a gate insulation layer 01 may be included between the semiconductor layer 102 and the first metal layer 103, and the gate insulation layer 01 may be made of silicon nitride (SiNx) material or silicon oxide (SiOx) material. An interlayer insulation layer 02 may be provided between the first metal layer 103 and the second metal layer 104. The interlayer insulation layer 02 may be a multilayer structure, that is, a nitride layer SiN containing silicon nitride (SiNx) and an oxide layer SiO containing silicon oxide (SiOx) may be alternately stacked. The active part 00TP (source connection area of the active part 00TP) of the thin-film transistor 00T of the semiconductor layer 102 may be electrically connected to the first terminal 00TS of the thin-film transistor 00T of the second metal layer 104 through the first via Ki. The first via K1 may be understood as a via hole provided in the interlayer insulation layer 02.

It can be understood that the shape of the pixel electrode 00P in FIG. 2 of this embodiment is only for illustration, and may be designed according to actual needs during specific implementation, and this embodiment does not limit this. The layout shape of each sub- pixel 00 in FIG. 2 is also only an example, and does not represent the only layout structure during actual setting. During a specific implementation, it can be set according to actual needs and the layout structure of the liquid crystal display panel in related technologies, and this embodiment will not be repeated here.

When the display panel 000 is driven to display, the thin-film transistor 00T of the sub-pixel 00 may be turned on under the control of the scan signal transmitted by the scan line G, and the voltage on the data line S may be transmitted to the second terminal 00TD of the thin- film transistor 00T through the first terminal 00TS of the thin-film transistor 00T, and the pixel electrode 00P may be driven. The electric field formed by the voltage difference between the pixel electrode 00P and the common electrode 00C (which is not filled in FIG. 4) may control the deflection of the liquid crystal of the liquid crystal layer 30 in each sub-pixel 00 region, thereby realizing the screen display of the display panel 000. It should be noted that the display principle of the display panel 000 is not described in detail in this embodiment, and the specific understanding may be referred to the driving display principle of the liquid crystal display panel in the relevant technology.

It can be understood that in FIG. 4 of this embodiment, the film layer where the common electrode 00C is located may be located on the side of the film layer where the pixel electrode 00P is located close to the first substrate 101. In a specific implementation, the film layer where the common electrode 00C is located may also be located on the side of the film layer where the pixel electrode 00P is located away from the first substrate 101, and this embodiment does not limit this.

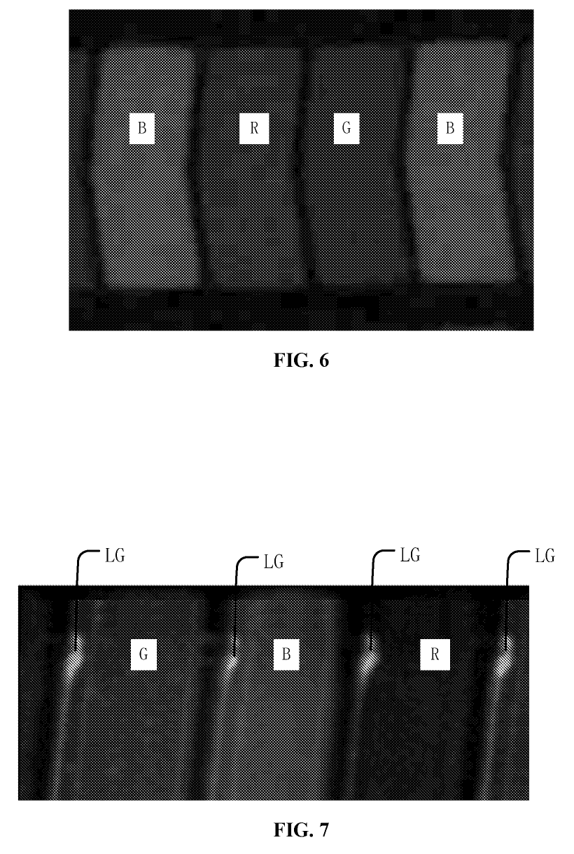

To improve the contrast ratio in the display panel, the conventional method is to increase the light-shielding area (i.e., light-shielding width) of the black matrix layer on the counter substrate side, that is, to reduce the metal light leakage phenomenon at the expense of the aperture ratio, as shown in FIG. 6, which is a display simulation diagram after increasing the light-shielding area of the black matrix layer on the counter substrate side in a certain embodiment. Although the contrast ratio is improved, the transmittance of the display panel decreases (the transmittance is not high), that is, the transmittance of the display panel is affected, affecting the display effect. It can be understood that the transmittance mentioned in this embodiment is a key indicator for measuring the light penetration ability of a liquid crystal display, and may usually be expressed in percentage form. The higher the value, the better the brightness and color expression of the display. To improve the transmittance, the light-shielding area (i.e., light-shielding width) of the black matrix layer on the counter substrate side may usually be compressed, as shown in FIG. 7, which is a display simulation diagram after compressing the light-shielding area of the black matrix layer on the counter substrate side in a certain embodiment. Although the transmittance is improved, once the alignment ability of the array substrate and the counter substrate is poor and the alignment is offset, the metal on the array substrate side will be easily exposed in the opening area defined by the black matrix layer on the counter substrate, especially the black matrix layer cannot completely block the metal light leakage at the via hole (LG position marked by each different color sub-pixel in FIG. 7, such as the red sub-pixel R, green sub-pixel G, and blue sub-pixel B area, i.e., the light leakage position refers to the first via hole K1 position in FIG. 2-FIG. 4), resulting in serious dark metal light leakage, and the contrast cannot meet the high demand of customers, resulting in a decrease in contrast, which will also affect the display quality.

To solve the above problem, the display panel 000 of the present embodiment may further include a third metal layer 105. The third metal layer 105 may be located between the first substrate 101 and the semiconductor layer 102, and the third metal layer 105 may include a plurality of first light-shielding members 1051. At the first via hole K1, the orthographic projection of the first via hole K1 on the first substrate 101 may at least be located within the orthographic projection range of the first light-shielding member 1051 on the first substrate 101, that is, the orthographic projection of the first light-shielding member 1051 on the first substrate 101 may cover the orthographic projection of the first via hole K1 on the first substrate 101. In this embodiment, the first light-shielding member 1051 may only be provided at the first via hole K1 where the metal light leakage is serious under the dark state display, and the orthographic projection of the first via hole K1 on the first substrate 101 may be the first projection K1T, and the orthographic projection of the first light-shielding member 1051 on the first substrate 101 may be the second projection 1051T, and the edge of the second projection 1051T may half surround the edge of the first projection K1T, that is, the second projection 1051T may not completely surround the first projection K1T, but only a portion of the edge of the second projection 1051T may be surrounded by the outer circle of the edge of the first projection K1T, and the other portions of the edges of the second projection 1051T may overlap or may be similar to overlap with portions of the edges of the first projection K1T (theoretically overlap, but the process errors that may exist due to process differences will not completely overlap).

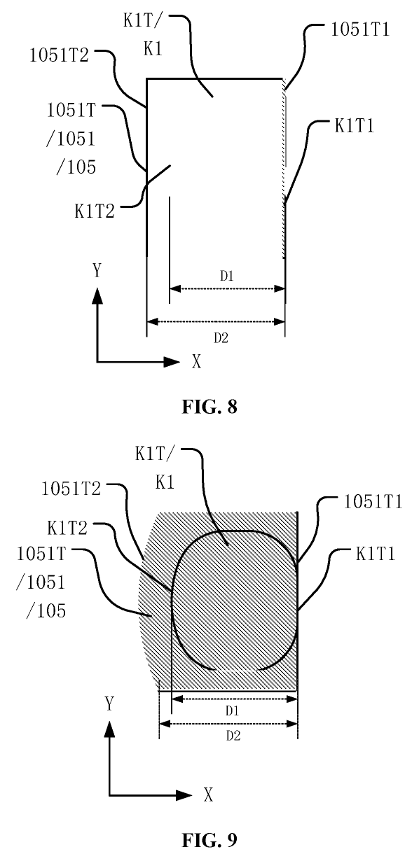

FIG. 8 is a schematic structural diagram of the first via hole and the first light- shielding member 1051 in FIGS. 2-3 being projected on the plane where the first substrate 101 is located (for the sake of clarity, other structures are omitted in FIG. 8, and only the first light- shielding member 1051 and the first via hole are projected on the plane where the first substrate 101 is located, and transparency is filled). As shown in FIG. 3 and FIG. 8, taking the shapes of the first projection K1T and the second projection 1051T as quadrilaterals as an example, three edges of the second projection 1051T may be on the outer circle of the edge of the first projection K1T, and another edge of the second projection 1051T may almost coincide with one edge of the first projection K1T. In one embodiment, the edge of the second projection 1051T surrounding the first projection K1T may include at least one of the left and right edges of the second projection 1051T in the first direction X. Because the position where the first via K1 is prone to the metal light leakage is generally on the left and right sides of the first via K1 (the two sides along the first direction X are understood as the left and right sides), and the upper and lower sides of the first via K1 (the two sides along the second direction Y are understood as the upper and lower sides) may be both shielded by the black matrix layer set on the side of the counter substrate 20, even if the array substrate 10 and the counter substrate 20 may be slightly offset after being attached, the black matrix layer in the second direction Y may not be affected.

Therefore, in one embodiment, a first light-shielding member 1051 may be arranged at the first via hole K1 where metal light leakage is serious under dark display. The orthographic projection of the first light-shielding member 1051 on the first substrate 101 may cover the orthographic projection of the first via hole K1 on the first substrate 101. The orthographic projection of the first via hole K1 on the first substrate 101 may be the first projection K1T. The orthographic projection of the first light-shielding member 1051 on the first substrate 101 may be the second projection 1051T. The edge of the second projection 1051T may only half surround the edge of the first projection K1T. The light leakage shielding may ensure the light-shielding effect and be to improve the contrast in the dark state display as much as possible. Moreover, the edge of the second projection 1051T formed by the first light- shielding member 1051 may be only the edge of the first projection K1T formed by half surrounding the first via hole Kl. Compared with related light-shielding structure, to ensure the light-shielding performance, the via hole may be generally completely covered and fully surrounded by the periphery of the via hole. In one embodiment, not only may it not need to widen the light-shielding width of the black matrix layer on the side of the counter substrate 20, but it may also not need to greatly increase the area of the first light-shielding member 1051 at the first via hole Kl. The edge of the second projection 1051T may only half surround the edge of the first projection K1T, so that the sacrificed opening area of the sub-pixel 00 may be minimized, and the dark state metal light leakage phenomenon may be reduced. In addition, because the pixel density in the existing liquid crystal display panel may be relatively high, the opening area of a single sub-pixel 00 is relatively small. Therefore, this embodiment may solve the metal light leakage problem at the first via K1 by sacrificing as little opening area of the sub- pixel 00 as possible, so that the sub-pixel 00 in the display panel 000 may still maintain a relatively high aperture ratio, so that it may have a better display performance, may take into account the requirements of high penetration and high contrast, and improve the overall display effect of the display panel 000.

It should be noted that the figure of this embodiment only illustrates the structure of the display panel. In specific implementation, the specific structure of the display panel includes but is not limited to this, and may also include other structures that can realize display functions or other functions such as touch functions. This embodiment will not be described in detail here, and details may be referred to the structure of the liquid crystal display panel in the relevant technology for understanding.

In one embodiment, the third metal layer 105 may be located between the semiconductor layer 102 and the first substrate 101. The third metal layer 105 may include other light-shielding structures, such as a light-shielding structure corresponding to the channel region of the thin-film transistor 00T (the region formed by the overlap of the gate and active part of the thin-film transistor), which may be used to block the backlight light in the channel region (in the liquid crystal display device, a backlight module may need to be set on the side of the first substrate 101 of the display panel 000 away from the counter substrate 20 to provide a backlight source), that is, to block the light from the backlight module to prevent the light from irradiating into the channel region of the thin-film transistor 00T, reduce the photogenerated carriers of the active part 00TP of the thin-film transistor 00T, thereby reducing the light leakage current of the thin-film transistor 00T, improving the conductive performance of the thin-film transistor 00T, reducing the display crosstalk phenomenon, and helping to improve the display quality.

In one embodiment, the first light-shielding member 1051 included in the display panel 000 may include the third metal layer 105 generally, that is, to improve the conductive performance of the thin-film transistor 00T, the common display panel 000 may be provided with a metal light-shielding layer such as the third metal layer 105 between the first substrate 101 and the semiconductor layer 102. Therefore, the first light-shielding member 1051 of this embodiment may multiplex the third metal layer 105 included in the display panel 000 itself, and there may be no need to add other film layers in the film layer structure of the array substrate 10 of the display panel 000, so that the metal light leakage problem may be reduced, which may be beneficial to improving the display quality while realizing the overall thin design of the panel.

FIG. 9 is another structural schematic diagram of the first via hole and the first light-shielding member in FIGS. 2-3 being projected on the plane where the first substrate is located (for the sake of clarity, other structures are omitted in FIG. 9, and only the first light- shielding member and the first via hole are projected on the plane where the first substrate is located, and transparency is filled). As shown in FIG. 9 and referring to FIGS. 1-5 and FIG. 8, in some embodiments, along the extension direction of the scan line G, that is, along the first direction X, the first projection K1T may include a first edge K1T1 and a second edge K1T2 that are opposite to each other. The first edge K1T1 may be toward the second terminal 00TD of the thin-film transistor 00T, and the second terminal K1T2 may be located on the side of the first edge K1T1 away from the second pole 00TD of the thin-film transistor 00T. The second projection 1051T may include a third edge 1051T1 and a fourth edge 1051T2 opposite to each other. The third edge 1051T1 may face the second terminal 00TD of the thin-film transistor 00T, and the fourth edge 1051T2 may be located on the side of the third edge 1051T1 away from the second terminal 00TD of the thin-film transistor 00T. The maximum distance between the first edge K1T1 and the second edge K1T2 may be D1, and the minimum distance between the third edge 1051T1 and the fourth edge 1051T2 may be D2. In one embodiment, D2>D1.

This embodiment explains that the shape of the first projection K1T may be square, circular, rectangular, or irregular, etc., and the shape of the second projection 1051T may also be square, circular, rectangular, or irregular, etc., and this embodiment does not limit this. However, no matter what the orthographic projection of the first via hole Ki on the first substrate 101 and the orthographic projection of the first light-shielding member 1051 on the first substrate 101 are, it may be necessary to satisfy that the second projection 1051T formed by the first light-shielding member 1051 covers the first projection K1T formed by the first via hole K1, and the edge of the second projection 1051T formed by the first light-shielding member 1051 may only half surround the edge of the first projection K1T formed by the first via hole Ki. Specifically, along the first direction X, that is, the overall extension direction of the scanning line G, no matter what the shape of the first projection K1T is, it may all include a first edge K1T facing the second terminal 00TD of the thin-film transistor 00T, and a second edge K1T2 located on the side of the first edge K1T1 away from the second terminal 00TD of the thin-film transistor 00T. No matter what shape the second projection 1051T is, it may all include a third edge 1051T1 facing the second terminal 00TD of the thin-film transistor 00T and a fourth edge 1051T2 located on the side of the third edge 1051T1 away from the second terminal 00TD of the thin-film transistor 00T. The maximum distance between the first edge K1T1 and the second edge K1T2 may be DL. In the first direction X, the maximum distance between the third edge 1051T1 and the second edge K1T2 may refer to a distance between a point on the first edge K1T1 that is farthest from the second edge K1T2 and a point on the second edge K1T2 that is farthest from the first edge K1T1. Similarly, the minimum distance between the third edge 1051T1 and the fourth edge 1051T2 may be D2. In the first direction X, the minimum distance between the third edge 1051T1 and the fourth edge 1051T2 may refer to a distance between a point on the third edge 1051T1 that is closest to the fourth edge 1051T2 and a point on the fourth edge 1051T2 that is closest to the third edge 1051T1 (as shown in FIG. 9 , the shape of the first projection K1T and the second projection 1051T is non-square or non-rectangular). D2 is greater than D1. Therefore, no matter what the shape of the first projection K1T and the second projection 1051T is, the minimum width of the first light-shielding member 1051 in the first direction X may have to be greater than the maximum width of the first via K1, thereby ensuring the light-shielding effect of the first light-shielding member 1051 on the metal light leakage at the first via K1, thereby improving the contrast and display quality in the dark state display.

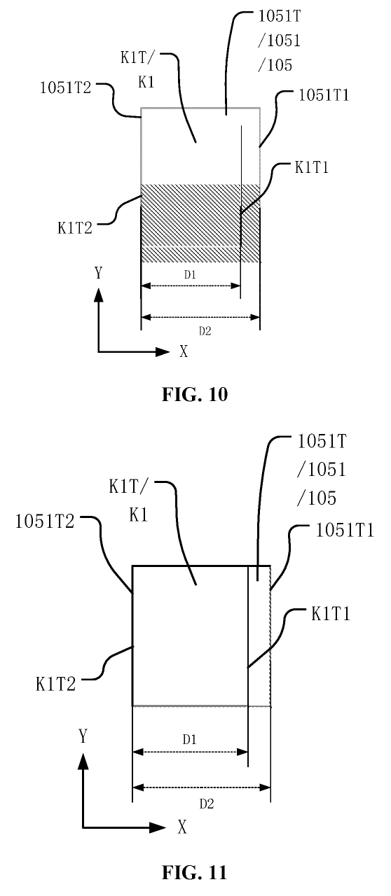

FIG. 10 is another structural schematic diagram of the first via hole and the first light-shielding member in FIGS. 2-3 being projected on the plane where the first substrate is located (for the sake of clarity, other structures are omitted in FIG. 10, and only the first light- shielding member and the first via hole are projected on the plane where the first substrate is located, and transparency is filled). In one embodiment, as shown in FIGS. 1-5, FIG. 8 and FIG. 10, the maximum distance D1 between the first edge K1T1 and the second edge K1T2 may be less than the minimum distance D2 between the third edge 1051T1 and the fourth edge 1051T2, then the third edge 1051T1 may be located on the side of the first edge K1T1 away from the second edge K1T2, and the fourth edge 1051T2 may be flush with the second edge K1T2, so that the second projection 1051T formed by the first light-shielding member 1051 may cover the first projection K1T formed by the first via hole K1, and the edge of the second projection 1051T formed by the first shading portion 1051 may be only the edge of the first projection K1T formed by the first via hole K1 that half surrounds.

FIG. 11 is another structural schematic diagram of the first via hole K1 and the first light shielding portion 1051 in FIGS. 2-3 being orthographically projected on the plane where the first substrate is located (for the sake of clarity, other structures are omitted in FIG. 11, and only the first light-shielding member and the first via hole are orthographically projected on the plane where the first substrate is located, and transparency filling is performed). As shown in FIGS. 1-5, FIG. 8 and FIG. 11, because the counter substrate 20 of the display panel 000 may generally include a black matrix layer (not shown in FIG. 11, refer to the counter substrate 20 in FIG. 5), along the second direction Y, at the corresponding position above the data line S, a black matrix layer extending along the second direction Y may be generally provided in the counter substrate 20 to block the reflected light of the data line S. Therefore, even if the edge of the second projection 1051T on both sides of the first via hole K1 in the second direction Y may be flush or substantially flush with the edge of the first projection K1T, the black matrix layer on the counter substrate 20 side may be used to block possible light leakage on both sides of the first via hole K1 in the second direction Y. Therefore, in this embodiment, the third edge 1051T1 may be arranged on the side of the first edge K1T1 away from the second edge K1T2, and the fourth edge 1051T2 may be flush with the second edge K1T2, so that the second projection 1051T formed by the first light-shielding member 1051 may cover the first projection K1T formed by the first via K1, and the edges of the second projection 1051T except the third edge 1051T1 may be arranged to be substantially flush or substantially overlap with the edges of the first projection K1T except the first edge K1T1, so that the manufacturing material of the first light-shielding member 1051 may be saved, and the cost may be saved. At the same time, the sub-pixel 00 in the display panel 000 may still maintain a high aperture ratio, and the edges of the first light-shielding member 1051 on both sides of the first via K1 in the second direction Y may be prevented from exceeding the edges of the first via K1 and affecting the transmittance of the region, which may be conducive to improving the display performance.

Referring to FIG. 7, based on the simulation results that the metal light leakage phenomenon occurring at the first via K1 may be generally manifested as unilateral light leakage. Therefore, the implementation of this embodiment as shown in FIG. 11 may not only solve the problem of metal light leakage at the first via K1, but also save the manufacturing materials of the first light-shielding member 1051, saving costs, and may also enable the sub- pixel 00 in the display panel 000 to still maintain a high aperture ratio, avoiding the edges of the first light shielding portion 1051 on both sides of the first via K1 in the second direction Y exceeding the edges of the first via K1 and affecting the transmittance of the area, which may be conducive to improving the transmittance of the sub-pixel 00 area, meeting the requirements of high transmittance and high contrast, and improving the overall display effect of the display panel 000.

In one embodiment, as shown in FIGS. 1-5 and FIG. 8, the maximum distance D1 between the first edge K1T1 and the second edge K1T2 may be less than the minimum distance D2 between the third edge 1051T1 and the fourth edge 1051T2, then the fourth edge 1051T2 may be located on the side of the second edge K1T2 away from the first edge K1T1, and the third edge 1051T1 may be flush with the first edge K1T1, so that the second projection 1051T formed by the first light-shielding member1051 may cover the first projection K1T formed by the first via K1, and the edge of the second projection 1051T formed by the first light-shielding member 1051 may only half surround the edge of the first projection K1T formed by the first via Kl.

FIG. 12 is another structural schematic diagram of the first via hole and the first light-shielding member in FIGS. 2-3 being orthographically projected on the plane where the first substrate is located (for the sake of clarity, other structures are omitted in FIG. 12, and only the first light-shielding member and the first via hole are orthographically projected on the plane where the first substrate is located, and transparency is filled). As shown in FIGS. 1-5, FIG. 8 and FIG. 12, because the counter substrate 20 of the display panel 000 may generally include a black matrix layer (not shown in FIG. 12, referring to the cross-sectional view on the side of the counter substrate 20 in FIG. 5) and the black matrix may be used to block the metal wiring on the side of the array substrate 10, along the second direction Y, and at the corresponding position above the data line S, a black matrix layer extending along the second direction Y may be generally provided in the counter substrate 20 to block the reflected light of the data line S. Therefore, even if the edge of the second projection 1051T on both sides of the first via hole K1 in the second direction Y may be flush or substantially flush with the edge of the first projection K1T, the black matrix layer on the side of the counter substrate 20 may also be used to block the possible light leakage on both sides of the first via hole K1 in the second direction Y. Therefore, in this embodiment, the fourth edge 1051T2 may be located on the side of the second edge K1T2 away from the first edge K1T1, and the third edge 1051T1 may be flush with the first edge K1T1, so that the second projection 1051T formed by the first light-shielding member 1051 may cover the first projection K1T formed by the first via Kl. At the same time, the edges of the second projection 1051T except the fourth edge 1051T2 may be set to be substantially flush or substantially coincidence with the edge of the first projection K1T except the second edge K1T2, so that the manufacturing material of the first light-shielding member 1051 may be saved, and the cost may be saved. At the same time, the sub-pixel 00 in the display panel 000 may still maintain a high aperture ratio, and the edges of the first light shielding portion 1051 on both sides of the first via K1 in the second direction Y may be prevented from exceeding the edges of the first via K1 and affecting the transmittance of the area, which may be conducive to improving the display performance.

Referring to FIG. 7, it has been found based on the simulation results that the metal light leakage phenomenon occurring at the first via K1 may be generally manifested as unilateral light leakage. Therefore, the implementation of this embodiment as shown in FIG. 12 may not only solve the problem of metal light leakage at the first via K1, but also save the manufacturing materials of the first light-shielding member 1051, save costs, and enable the sub- pixel 00 in the display panel 000 to still maintain a high aperture ratio, avoiding the edges of the first light-shielding member 1051 on both sides of the first via K1 in the second direction Y exceeding the edges of the first via K1 and affecting the transmittance of the area, which may be conducive to improving the transmittance of the sub-pixel 00 area, meeting the requirements of high transmittance and high contrast, and improving the overall display effect of the display panel 000.

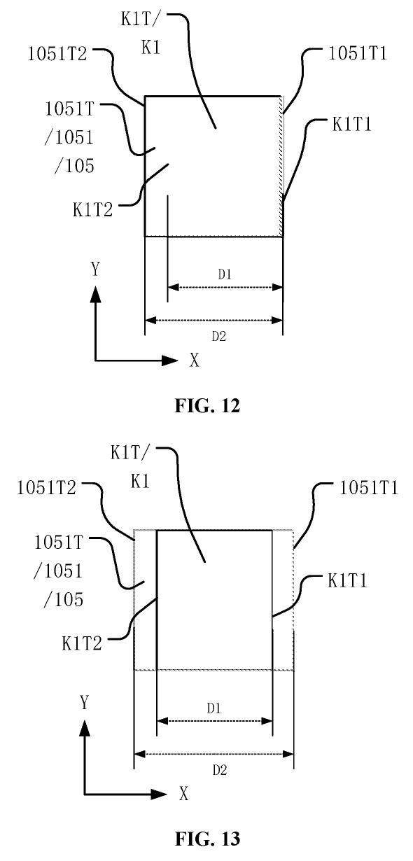

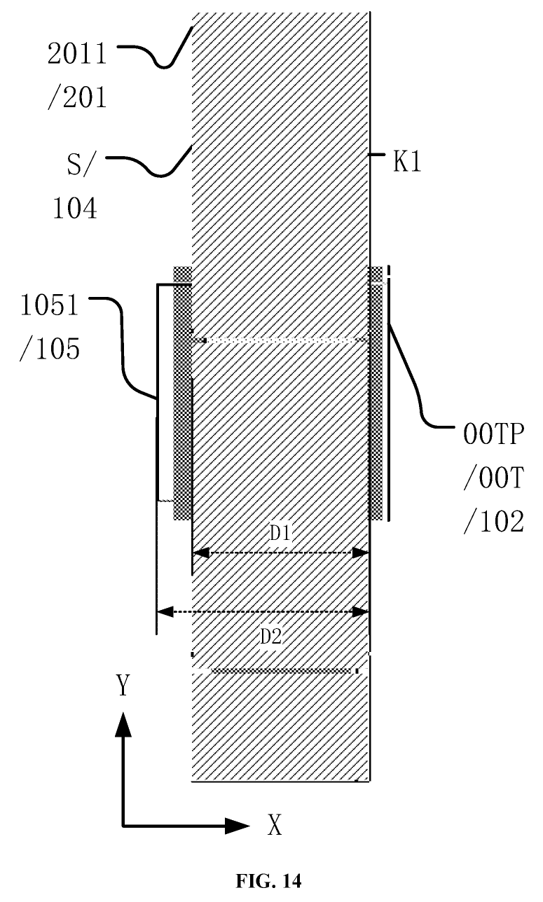

FIG. 13 is another structural schematic diagram of the first via hole and the first light-shielding member in FIGS. 2-3 being projected on the plane where the first substrate is located (for the sake of clarity, other structures are omitted in FIG. 13, and only the first light- shielding member and the first via hole are projected on the plane where the first substrate is located, and transparency is filled). As shown in FIGS. 1-5, FIG. 8 and FIG. 13, in one embodiment, the maximum distance D1 between the first edge K1T1 and the second edge K1T2 may be less than the minimum distance D2 between the third edge 1051T1 and the fourth edge 1051T2, then the third edge 1051T1 may be located at the side of the first edge K1T1 away from the second edge K1T2, and the third edge 1051T1 may be located at the side of the first edge K1T1 away from the second edge K1T2. The fourth edge 1051T2 may be located at the side of the second edge K1T2 away from the first edge K1T1. At this time, the second projection 1051T formed by the first light-shielding member 1051 may cover the first projection K1T formed by the first via Kl. To achieve that the edge of the second projection 1051T formed by the first shading portion 1051 only half surrounds the edge of the first projection K1T formed by the first via K1, the edge of the second projection 1051T except the third edge 1051T1 and the fourth edge 1051T2 may be set to be basically flush with or basically overlap with the edges of the first projection K1T except the first edge K1T1 and the second edge K1T2. As shown in FIG. 13, because the counter substrate 20 of the display panel 000 may generally include a black matrix layer (not shown in FIG. 13, referring to the cross-sectional view of the counter substrate 20 side in FIG. 5), for shielding the metal wiring on the array substrate 10 side, a black matrix layer extending along the second direction Y may be generally provided in the counter substrate 20 at a corresponding position above the data line S to shield the reflected light of the data line S. Therefore, even if the edge of the second projection 1051T at both sides of the first via K1 in the second direction Y may be flush or substantially flush with the edge of the first projection K1T, the black matrix layer on the counter substrate 20 side may be used to shield the possible light leakage at both sides of the first via K1 in the second direction Y.

In one embodiment, the third edge 1051T1 may be located at the side of the first edge K1T1 away from the second edge K1T2, and the fourth edge 1051T2 may be located at the side of the second edge K1T2 away from the first edge K1T1, which may satisfy that the second projection 1051T formed by the first light-shielding member 1051 covers the first projection K1T formed by the first via Kl. At the same time, to realize that the edge of the second projection 1051T formed by the first light-shielding member 1051 only half surrounds the edge of the first projection K1T formed by the first via K1, the edges of the second projection 1051T other than the third edge 1051T1 and the fourth edge 1051T2 may be set. The edges other than the first edge K1T1 and the second edge K1T2 in the first projection K1T may be basically flush or basically overlapped, so that the manufacturing material of the first light-shielding member 1051 may be saved, saving costs, and the sub-pixel 00 in the display panel 000 may still maintain a relatively high aperture ratio, avoiding the edges of the first light shielding member 1051 at both sides of the first via hole K1 in the second direction Y exceeding the edge of the first via hole K1 and affecting the transmittance of the area, which may be beneficial to improving the display performance, and further solving the problem of metal light leakage at the first via hole K1, achieving the requirements of high transmittance and high contrast, and improving the overall display effect of the display panel 000.

FIG. 14 is another partially enlarged schematic diagram of the J2 area in FIG. 2 (it can be understood that, to clearly illustrate the structure of this embodiment, the black matrix layer is not illustrated in FIG. 2, and FIG. 14 is filled with transparency). In one embodiment, as shown in FIGS. 1-2 and FIG. 14, one side of the counter substrate 20 may also include a black matrix layer 201, and the black matrix layer 201 may include a plurality of first light-shielding strips 2011 and a plurality of second light-shielding strips (not illustrated in the figure) of the same layer. The first light-shielding strips 2011 and the second light-shielding strips may be cross-arranged to form a mesh structure, and the extension direction of the first light-shielding strips 2011 may be same as the extension direction of the data line S, that is, it can be understood that the overall extension direction of the first light-shielding strips 2011 may be the second direction Y, and the overall extension direction of the second light-shielding strips may be the first direction X. As shown in FIG. 14, even if the edges of the second projection 1051T at both sides of the first via K1 in the second direction Y are flush or substantially flush with the edge of the first projection K1T, the first light-shielding strip 2011 of the black matrix layer 201 on the counter substrate 20 side may be used to shield the possible light leakage at both sides of the first via K1 in the second direction Y, and then the first light-shielding member 1051 may only need to consider the light-shielding effect at both sides of the first via K1 in the first direction X.

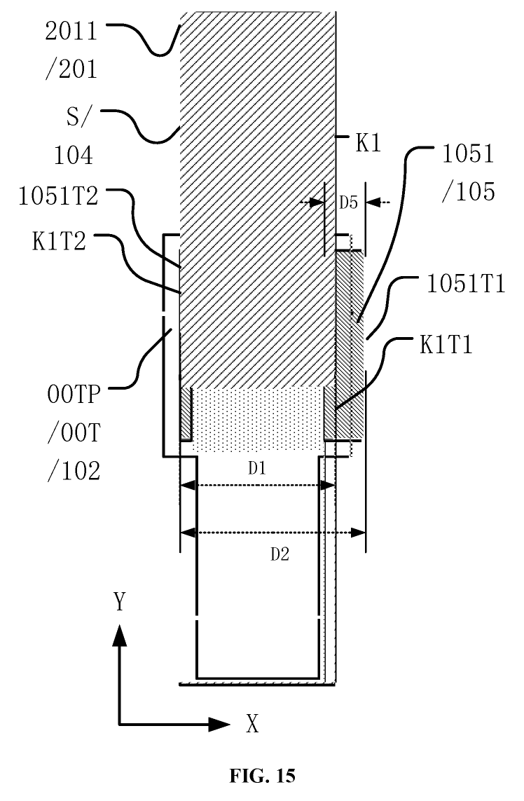

FIG. 15 is another partially enlarged schematic diagram of the J2 area in FIG. 2 (it can be understood that, to clearly illustrate the structure of this embodiment, the black matrix layer is not shown in FIG. 2, and FIG. 15 is filled with transparency). In one embodiment, as shown in FIGS. 1-2 and FIG. 15, along the extension direction of the scan line G, that is, along the first direction X, the minimum distance D5 of the third edge 1051T1 beyond the edge of the data line S may be 2-2.2 m.

This embodiment explains that the second projection 1051T formed by the first light-shielding member 1051 may cover the first projection K1T formed by the first via K1 to ensure that the metal light leakage problem at the first via K1 may be reduced. At the same time, to achieve that the edge of the second projection 1051T formed by the first light-shielding member 1051 only half surrounds the edge of the first projection K1T formed by the first via K1 and improve the transmittance, the second projection 1051T formed by the first light-shielding member 1051 may be set to have a single-sided outward expansion structure compared to the first projection K1T formed by the first via K1, that is, along the first direction X, the third edge 1051T1 of the second projection 1051T may exceed the first edge K1T1 of the first projection K1T, and the other edges of the second projection 1051T may be substantially flush with or substantially coincide with the other edges of the first projection K1T. At this time, to ensure the light-shielding effect of the first light-shielding member 1051 at the first via K1, the minimum distance D5 of the third edge 1051T1 beyond the edge of the data line S along the first direction X may be set to 2-2.2 m, that is, along the first direction X, the distance between the third edge 1051T1 and the nearest edge of the data line S may be between 2-2.2 m. Even if a slight misalignment occurs in the first direction X when the array substrate 10 and the counter substrate 20 are aligned and packaged, the two sides of the first light-shielding strip 2011 in the first direction X may not provide good light-shielding for the two sides of the first via Kl. The light shielding effect of the first light-shielding member 1051 on the first via K1 in the first direction X may be ensured. In addition, along the first direction X, the distance between the third edge 1051T1 and the nearest edge of the data line S may be 2-2.2μm, which may ensure that the width of the first light-shielding member 1051 in the first direction X is not too large to affect the transmittance of the display panel 000, thereby achieving both high transmittance and high contrast display effects.

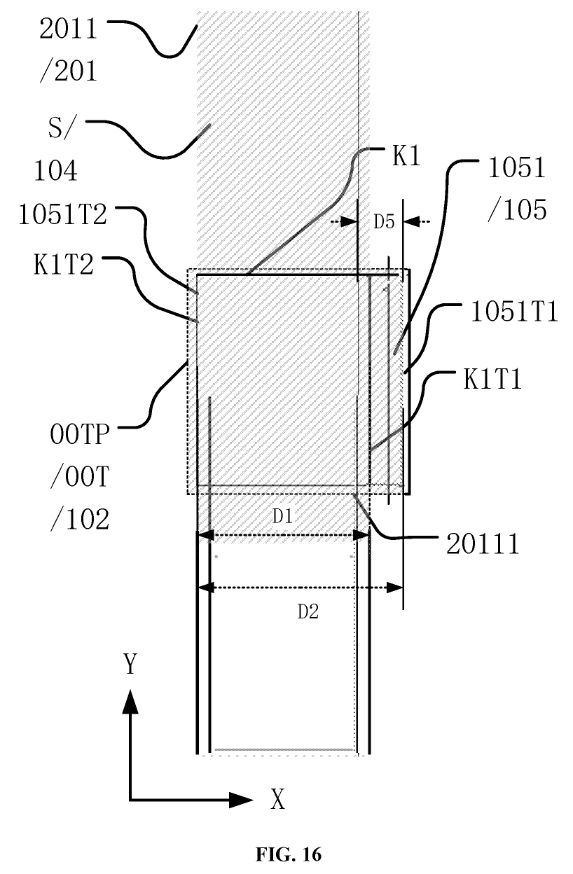

FIG. 16 is another partially enlarged schematic diagram of the J2 area in FIG. 2 (it can be understood that, to clearly illustrate the structure of this embodiment, the black matrix layer is not shown in FIG. 2, and FIG. 16 is filled with transparency). In some embodiments, as shown in FIGS. 1-2 and FIG. 16, one side of the counter substrate 20 may also include a black matrix layer 201, and the black matrix layer 201 may include a plurality of first light-shielding strips 2011 and a plurality of second light-shielding strips (not shown in the figure) of the same layer. The first light-shielding strips 2011 and the second light-shielding strips may be cross- arranged to form a mesh structure. The extension direction of the first light-shielding strip 2011 may be same as the extension direction of the data line S, that is, it can be understood that the overall extension direction of the first light-shielding strips 2011 may be the second direction Y, and the overall extension direction of the second light-shielding strips may be the first direction X.

The first light-shielding strip 2011 may include a first protrude portion 20111, and the orthographic projection of the first light-shielding member 1051 on the first substrate 101 may be located within the orthographic projection range of the first protrude portion 20111 on the first substrate 101.

This embodiment explains that the first light-shielding strip 2011 of the black matrix layer 201 may be understood as a structure with the same extension direction as the data line S, that is, the first light-shielding strip 2011 may be understood as being arranged above the data line S to shield the reflection of the metal material of the data line S, so as to prevent the reflected light of the metal material of the data line S from affecting the display quality. This embodiment may further arrange the first light-shielding strip 2011 including the first protrude portion 20111 at the position corresponding to the first via K1, so that the orthographic projection of the first light-shielding member 1051 on the first substrate 101 may be located within the orthographic projection range of the first protrude portion 20111 on the first substrate 101. Because the first light-shielding member 1051 may be made of the third metal layer 105, that is, the first light-shielding member 1051 may also be made of metal material, the first light- shielding member 1051 may be exposed outside the shielding range of the black matrix layer 201 after expanding in the first direction X. Therefore, in this embodiment, a first light-shielding strip 2011 including a first protrude portion 20111 may be arranged at the position corresponding to the first via K1, that is, the first light-shielding strip 2011 may also be expanded in the first direction X to form the first protrude portion 20111 at the position of the first light-shielding member 1051, that is, at the position of the first via K1, and the orthographic projection of the first light-shielding member 1051 on the first substrate 101 may be located within the orthographic projection range of the first protrude portion 20111 on the first substrate 101, thereby shielding the metal reflection of the first light-shielding member 1051 from affecting the display effect.

In one embodiment, at the position of the first via hole K1, the orthographic projection of the first light-shielding member 1051 on the first substrate 101 may be located within the orthographic projection range of the first protrude portion 20111 on the first substrate 101, and the orthographic projection area of the first protrude portion 20111 on the first substrate 101 may cover the orthographic projection area of the first light-shielding member 1051 on the first substrate 101, and the orthographic projection area of the first protrude portion 20111 on the first substrate 101 may be larger than the orthographic projection area of the first light-shielding member 1051 on the first substrate 101 (as shown in FIG. 16), thereby ensuring the shielding effect of the first protrude portion 20111 of the first light-shielding strip 2011 on the reflected light of the first light-shielding member 1051.

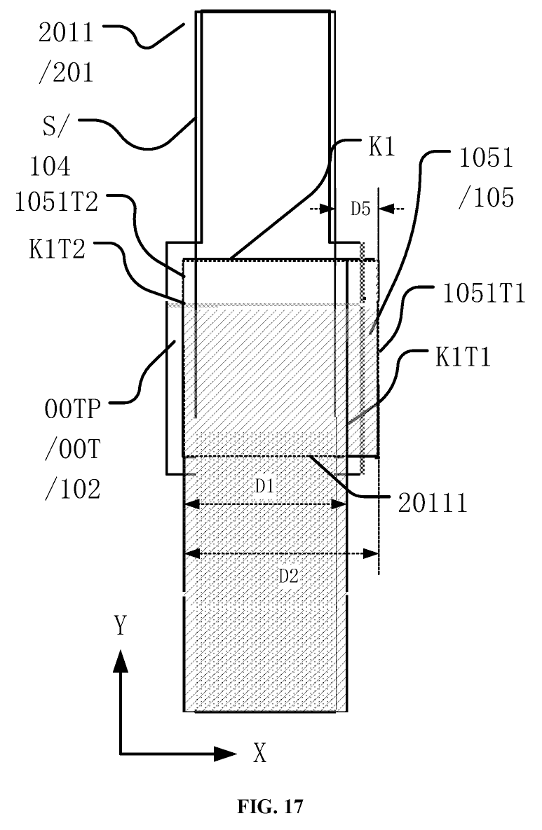

FIG. 17 is another partially enlarged schematic diagram of the J2 region in FIG. 2 (it can be understood that, to clearly illustrate the structure of this embodiment, the black matrix layer is not illustrated in FIG. 2, and FIG. 17 is filled with transparency). In some embodiments, as shown in FIGS. 1-2 and FIG. 17, the orthographic projection of the first light-shielding member 1051 on the first substrate 101 may be arranged to coincide with the orthographic projection of the first protrude portion 20111 on the first substrate 101, that is, the orthographic projection of the first protrude portion 20111 on the first substrate 101 may cover the orthographic projection of the first light-shielding member 1051 on the first substrate 101 and the orthographic projection area of the first protruding portion 20111 on the first substrate 101 may be equal to the orthographic projection area of the first light-shielding member 1051 on the first substrate 101 (as shown in FIG. 17), thereby ensuring the shielding effect of the first protrude portion 20111 of the first light-shielding strip 2011 on the reflected light of the first light- shielding member 1051, and reducing the layout area of the first light-shielding strip 2011, i.e., the black matrix layer 201, which may be beneficial to improving the transmittance of the display panel 000.

It can be understood that FIG. 16 and FIG. 17 only illustrate the arrangement structure of the first protrude portion 20111 of the first light-shielding strip 2011 when the first light-shielding member 1051 expands outward on the right side in the first direction X. In specific implementation, if the first light-shielding member 1051 may expand outward on both sides of the left and right sides in the first direction X, the arrangement structure of the first protrude portion 20111 of the first light-shielding strip 2011 may also change with the shape of the first light-shielding member 1051, and it may be only required to meet the requirement that the orthographic projection of the first light-shielding member 1051 on the first substrate 101 may be within the orthographic projection range of the first protrude portion 20111 on the first substrate 101 at the position of the first via K1, so as to play the role of shielding the metal reflection effect of the first light-shielding member 1051.

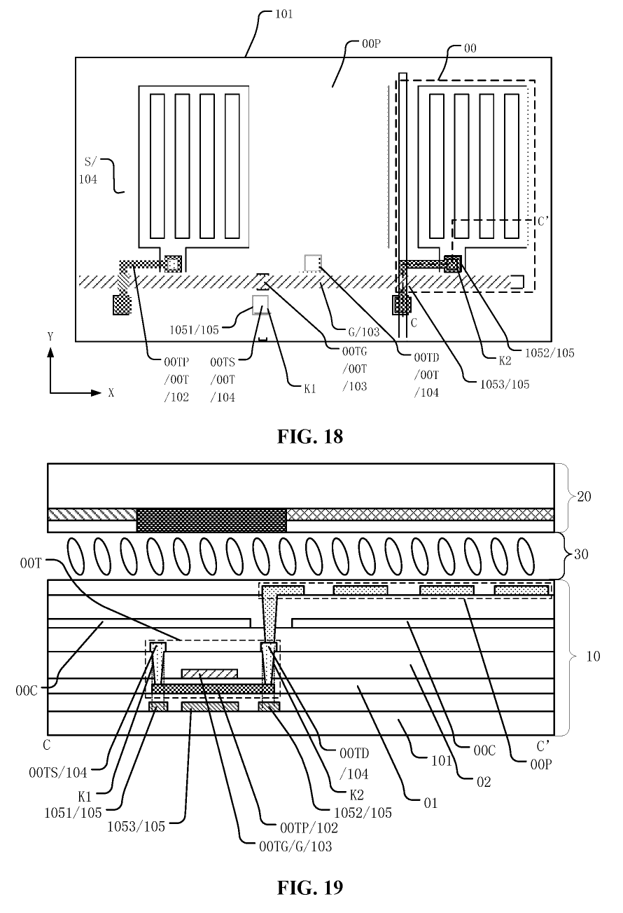

FIG. 18 is another partially enlarged schematic diagram of the J1 area in FIG. 1, and FIG. 19 is a cross-sectional structural schematic diagram of the C-C' direction in FIG. 18 (it can be understood that, to clearly illustrate the structure of this embodiment, FIG. 18 is filled with transparency). In some embodiments, as shown in FIG. 1, FIG. 18 and FIG. 19, the shape of the orthographic projection of the active part 00TP of the thin-film transistor 00T on the first substrate 101 may be an L-shaped. It can be understood that the shape of the orthographic projection of the active part 00TP of the thin-film transistor 00T on the first substrate 101 in this embodiment may be that the overall shape of the active part 00TP may be L-shaped, which may not mean that the shape of the positive projection of the active part 00TP of the thin-film transistor 00T on the first substrate 101 is a standard L-shape (as shown in FIG. 2).

In one embodiment, the active part 00TP of the thin-film transistor 00T may be electrically connected to the second terminal 00TD of the thin-film transistor 00T through the second via K2. The third metal layer 105 may also include a plurality of second light-shielding members 1052 and a plurality of third light-shielding members 1053.

At the second via K2, the orthographic projection of the second via K2 on the first substrate 101 may be at least located within the orthographic projection range of the second light-shielding members 1052 on the first substrate 101. The orthographic projection of the third light-shielding members 1053 on the first substrate 101 may cover the orthographic projection of the channel region of the thin-film transistor 00T on the first substrate 101. The first light- shielding member 1051, the second light-shielding member 1052, and the third light-shielding member 1053 may be independent structures respectively.

This embodiment explains that the third metal layer 105 may be located between the semiconductor layer 102 and the first substrate 101. The third metal layer 105 may include other light-shielding structures, such as a third light-shielding member 1053 corresponding to the channel region of the thin-film transistor 00T (the region formed by the overlap of the gate and the active portion of the thin-film transistor). The third light-shielding member 1053 may be used to block the backlight in the channel region (in a liquid crystal display device, a backlight module needs to be provided on the side of the first substrate 101 of the display panel 000 away from the counter substrate 20 to provide a backlight source), that is, to block the light from the backlight module to prevent the light from irradiating into the channel region of the thin-film transistor 00T, thereby reducing the photogenerated carriers in the active part 00TP of the thin- film transistor 00T, thereby reducing the light leakage current of the thin-film transistor 00T, improving the conductive performance of the thin-film transistor 00T, reducing the display crosstalk phenomenon, and helping to improve the display quality. The third metal layer 105 may also include other light-shielding structures. For example, at the second via hole K2, the orthographic projection of the second light-shielding member 1052 on the first substrate 101 may cover the orthographic projection of the second via hole K2 on the first substrate 101. The second light-shielding member 1052 may solve the metal light leakage problem at the second via hole K2, which may be conducive to further improving the display contrast.

Because the shape of the orthographic projection of the active part 00TP of the thin-film transistor 00T in the present embodiment on the first substrate 101 may be L-shaped as a whole, the first via K1, the channel region of the thin-film transistor 00T and the second via K2 may be relatively dispersed in the direction parallel to the plane where the display panel 000 is located. Therefore, for the same sub-pixel 00 area, the first light-shielding member1051, the second light-shielding member 1052, and the third light-shielding member 1053 provided by the third metal layer 105 may be independent structures respectively, so as to avoid the first light- shielding member 1051, the second light-shielding member 1052, and the third light-shielding member 1053 being integrated to cause the metal light-shielding area to be too large, which affects the aperture ratio of the sub-pixel 00, thereby helping to improve the overall transmittance of the panel and ensure the display quality.

It can be understood that in this embodiment and the drawings of the above- mentioned embodiments, the shape of the orthographic projection of the active part 00TP of the thin-film transistor 00T on the first substrate 101 is L-shaped as an example for illustration. In specific implementation, the shape of the orthographic projection of the active part 00TP of the thin-film transistor 00T on the first substrate 101 may also be other shapes as a whole, such as a large U shape or a small U shape, etc. This embodiment does not limit this. In specific implementation, it can be set according to the actual needs of the display panel 000.

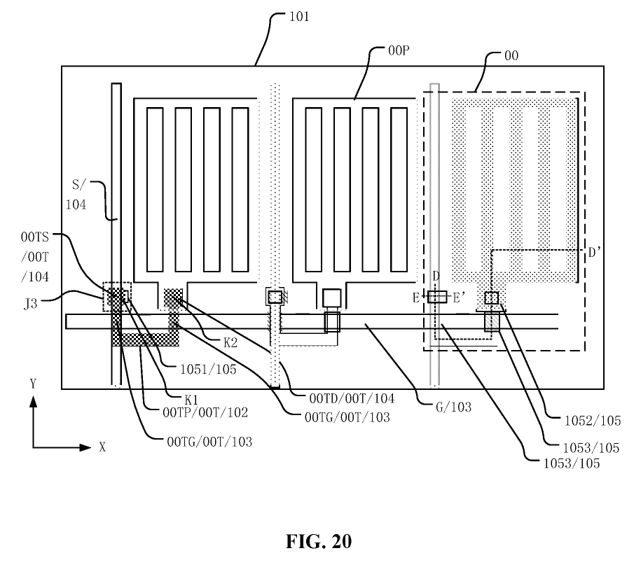

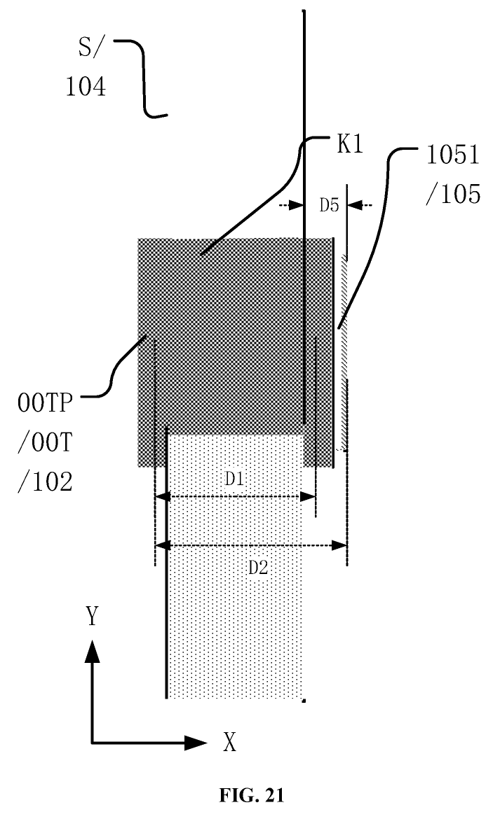

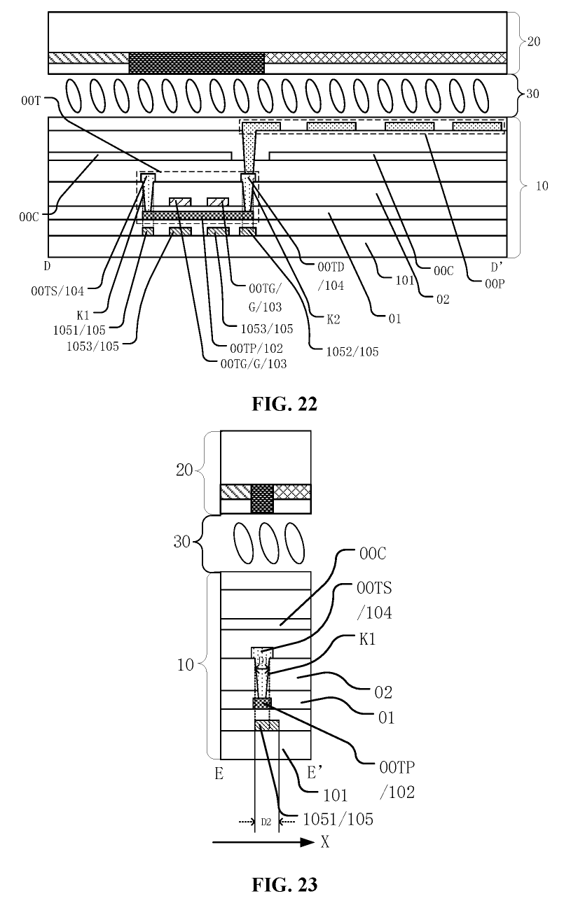

FIG. 20 is another partial enlarged schematic diagram of the Ji area in FIG. 1, FIG. 21 is a partial enlarged schematic diagram of the J3 area in FIG. 20, FIG. 22 is a cross- sectional structural schematic diagram of the D-D' direction in FIG. 20, and FIG. 23 is a cross- sectional structural schematic diagram of the E-E' direction in FIG. 20 (it can be understood that, to clearly illustrate the structure of this embodiment, FIGS. 20-21 are filled with transparency). As shown in FIG. 1 and FIGS. 20-23, in some embodiments, the shape of the orthographic projection of the active part 00TP of the thin-film transistor 00T on the first substrate 101 may be U-shaped.

This embodiment explains that the design of the thin-film transistor 00T arranged on the side of the array substrate 10 in the display panel 000 may be that the shape of the orthographic projection of the active part 00TP of the thin-film transistor 00T on the first substrate 101 may be U-shaped, and the thin-film transistor 00Tmay include two gates 00TG. The thin-film transistor 00T may have the advantages of high input impedance, low power consumption of voltage control, simple control circuit, high voltage resistance, and large current bearing. The shape of the orthographic projection of the active part 00TP of the thin-film transistor 00T on the first substrate 101 is U-shaped, and the entire structure of the thin-film transistor 00T may be compressed to the maximum extent in the sub-pixel 00 area, so that the first via K1, the channel area of the thin-film transistor 00T, and the second via K2 may be arranged in a relatively concentrated position in the direction parallel to the plane where the display panel 000 is located, which may be conducive to improving the transmittance of the display panel 000.

It can be understood that this embodiment does not limit the shape of the orthographic projection of the active part 00TP of the thin-film transistor 00T on the first substrate 101, and no matter what shape it is, it may satisfy that at the first via hole K1, the orthographic projection of the first via hole K1 on the first substrate 101 may be at least located within the orthographic projection range of the first light-shielding portion 1051 on the first substrate 101. The orthographic projection of the first via hole K1 on the first substrate 101 may be the first projection, and the positive projection of the first light-shielding portion 1051 on the first substrate 101 may be the second projection, and the edge of the second projection may half surround the edge of the first projection, so as to meet the requirements of high transmittance and high contrast, and improve the overall display effect of the display panel 000. When the shape of the orthographic projection of the active part 00TP of the thin-film transistor 00T on the first substrate 101 is U-shaped, the setting of the first light-shielding member1051 may be understood and set with reference to any of the above embodiments, and this embodiment will not be repeated here.

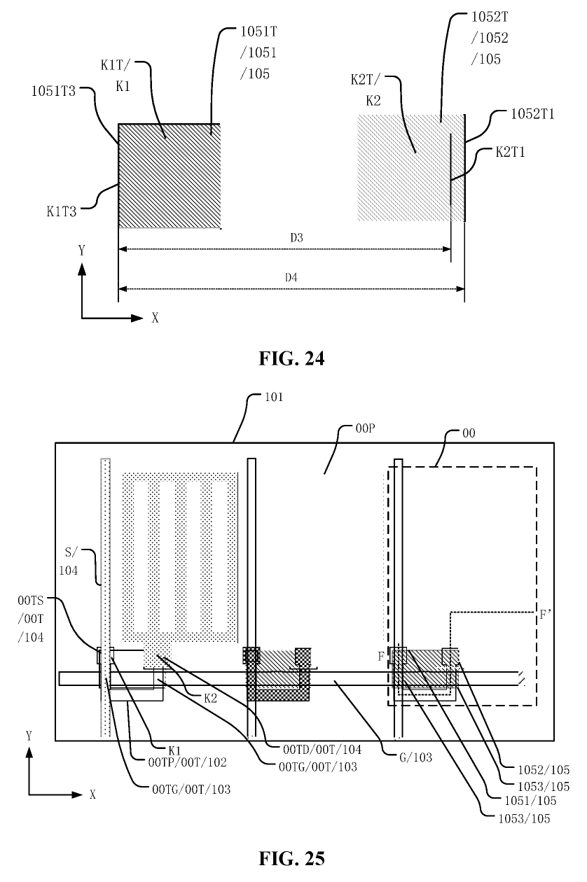

FIG. 24 is a schematic structural diagram of the first via hole and the first light- shielding member, the second via hole and the second light-shielding member in FIG. 20 being orthographically projected on the plane where the first substrate is located (it can be understood that, to clearly illustrate the structure of this embodiment, the black matrix layer is not illustrated in FIG. 20, and FIG. 24 is filled with transparency, and FIG. 24 omits some other structures, and only the orthographic projection of the first light-shielding member and the first via hole on the plane where the first substrate is located, and the orthographic projection of the second light- shielding member and the second via hole on the plane where the first substrate is located are shown). In one embodiment, as shown in FIG. 1, FIG. 20-FIG. 23, and FIG. 24, the third metal layer 105 may also include a plurality of second light-shielding members 1052.

The active portion 00TP of the thin-film transistor 00T may be electrically connected to the second terminal 00TD of the thin-film transistor 00T through the second via hole K2. The orthographic projection of the second via hole K2 on the first substrate 101 may be located within the orthographic projection range of the second light-shielding member 1052 on the first substrate 101.

The orthographic projection of the second via K2 on the first substrate 101 may be the third projection K2T. The orthographic projection of the second light-shielding member 1052 on the first substrate 101 may be the fourth projection 1052T.

Along the extension direction of the scan line G, that is, along the first direction X, the first projection K1T may include a fifth edge K1T3 away from the third projection K2T. The third projection K2T may include a sixth edge K2T1 away from the first projection K1T. The second projection 1051T may include a seventh edge 1051T3 away from the fourth projection 1052T. The fourth projection 1052T may include an eighth edge 1052T1 away from the second projection 1051T.

The maximum distance between the fifth edge K1T3 and the sixth edge K2T1 may be D3. The minimum distance between the seventh edge 1051T3 and the eighth edge 1052T1 may be D4. D4>D3. In one embodiment, D4-D3<1tm.

This embodiment explains that the active part 00TP of the thin-film transistor 00T may be electrically connected to the second terminal 00TD of the thin-film transistor 00T through the second via hole K2. Metal light leakage may also occur at the second via hole K2. Therefore, a second light-shielding member 1052 may also be provided on the third metal layer 105, so that the orthographic projection of the second via hole K2 on the first substrate 101 may be located within the orthographic projection range of the second light-shielding portion 1052 on the first substrate 101. The second light-shielding member 1052 may reduce the problem of metal light leakage at the second via hole K2.

In addition, in this embodiment, if the orthographic projection of the second via hole K2 on the first substrate 101 is named the third projection K2T, and the orthographic projection of the second light-shielding member 1052 on the first substrate 101 is named the fourth projection 1052T, then along the extension direction of the scan line G, that is, along the first direction X, the first projection K1T may include a fifth edge K1T3 away from the third projection K2T. The third projection K2T may include a sixth edge K2T1 away from the first projection K1T. The second projection 1051T may include a seventh edge 1051T3 away from the fourth projection 1052T. The fourth projection 1052T may include the eighth edge 1052T1 away from the second projection 1051T. The maximum distance D3 between the fifth edge K1T3 and the sixth edge K2T1 may be less than the minimum distance D4 between the seventh edge 1051T3 and the eighth edge 1052T1.

In the first direction X, the maximum distance between the fifth edge K1T3 and the sixth edge K2T1 may refer to a distance D2 between the point of the fifth edge K1T3 farthest from the sixth edge K2T1 and the point of the sixth edge K2T1 farthest from the fifth edge K1T3. Similarly, in the first direction X, the minimum distance between the seventh edge 1051T3 and the eighth edge 1052T1 may refer to the distance D4 between a point of the seventh edge 1051T3 closest to the eighth edge 1052T1 and a point of the eighth edge 1052T1 closest to the seventh edge 1051T3 (as shown in FIG. 24, taking the shapes of the first projection K1T, the second projection 1051T, the third projection K2T, and the fourth projection 1052T as a square as an example). D4 may be greater than D3. Therefore, no matter what shapes the first projection K1T, the second projection 1051T, the third projection K2T, and the fourth projection 1052T have, they may all satisfy that, in the first direction X, the minimum width of the first light-shielding member 1051 may be greater than the maximum width of the first via K1, and the minimum width of the second light-shielding member 1052 may be greater than the maximum width of the second via K2, thereby ensuring the light-shielding effect of the first light-shielding member 1051 on metal light leakage at the first via K1 and the light-shielding effect of the second light-shielding member 1052 on metal light leakage at the second via K2, further improving the contrast and display quality under dark display.

Further, as shown in FIG. 1, FIG. 20-FIG. 23 , and FIG. 24, in some embodiments, along the first direction X, the first projection K1T may include a fifth edge K1T3 away from the third projection K2T, the third projection K2T may include a sixth edge K2T1 away from the first projection K1T, the second projection 1051T may include a seventh edge 1051T3 away from the fourth projection 1052T, and the fourth projection 1052T may include an eighth edge 1052T1 away from the second projection 1051T. The maximum distance D3 between the fifth edge K1T3 and the sixth edge K2T1 may be less than the minimum distance D4 between the seventh edge 1051T3 and the eighth edge 1052T1, and D4-D3<1tm, so that the light-shielding effect of the first light-shielding member 1051 at the first via K1 and the light- shielding effect of the second light-shielding member 1052 at the second via K2 may be ensured, while avoiding the excessive width of the first light-shielding member 1051 and the second light- shielding member 1052 in the first direction X affecting the transmittance of the display panel 000, thereby achieving a display performance that takes into account both high contrast and high transmittance.

In some embodiments, referring to FIG. 1 and FIGS. 20-23, the third metal layer 105 may also include a plurality of third light-shielding members 1053. The orthographic projection of the channel region of the thin-film transistor 00T on the first substrate 101 may be located within the positive projection range of the third light-shielding member1053 on the first substrate 101.

The third light-shielding member 1053 may be used to shield the backlight in the channel region (in the liquid crystal display device, a backlight module needs to be set on the side of the first substrate 101 of the display panel 000 away from the counter substrate 20 to provide a backlight source), that is, to shield the light from the backlight module to prevent the light from irradiating into the channel region of the thin-film transistor 00T, to reduce the photogenerated carriers of the active portion 00TP of the thin-film transistor 00T, thereby reducing the light leakage current of the thin-film transistor 00T, improving the conductive performance of the thin-film transistor 00T, reducing the display crosstalk phenomenon, and helping to improve the display quality.

In some embodiments, as shown in FIG. 20 and FIG. 22, the first light-shielding member 1051, the second light-shielding member 1052, and the third light-shielding member 1053 may be independent structures. Accordingly, the layout area of the third metal layer 105 may be minimized, the transmittance of the display panel 000 may be maximized, and the display quality may be guaranteed.

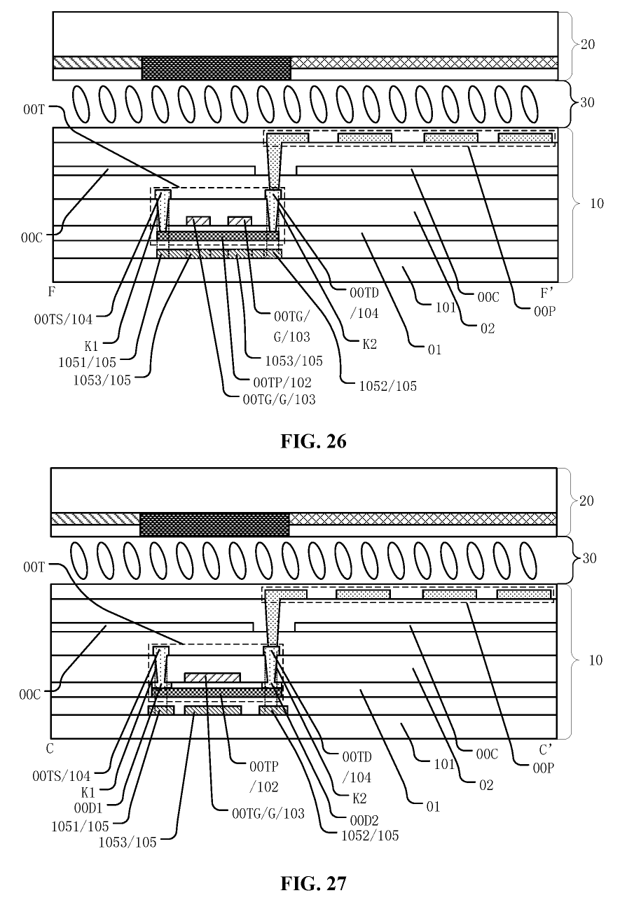

FIG. 25 is another partially enlarged schematic diagram of the J1 region in FIG. 1, and FIG. 26 is a cross-sectional structural schematic diagram of the F-F' direction in FIG. 25 (it can be understood that, to clearly illustrate the structure of this embodiment, FIG. 25 is filled with transparency). In one embodiment, as shown in FIG. 1, FIG. 25 and FIG. 26, the first light- shielding member 1051, the second light-shielding member 1052, and the third light-shielding portion 1053 may be an integrated structure.

This embodiment explains that in the display panel 000, the shape of the orthographic projection of the active part 00TP of the thin-film transistor 00T on the first substrate 101 may be U-shaped, and the entire structure of the thin-film transistor 00T may be compressed to the maximum extent in the sub-pixel 00 region, so that the first via K1, the channel region of the thin-film transistor 00T, and the second via K2 may be arranged in a relatively concentrated position in the direction parallel to the plane where the display panel 000 is located, which may be conductive to improving the transmittance of the display panel 000. At this time, the first light-shielding member 1051 corresponding to the first via K1, the second light-shielding member 1052 corresponding to the second via K2, and the third light-shielding member 1053 corresponding to the channel region of the thin-film transistor 00T may be an integrated structure, that is, it can be understood that for a single sub-pixel 00, the first light- shielding member 1051, the second light-shielding member 1052, and the third light-shielding member 1053 may be an entire structure. Because the shape of the orthographic projection of the active portion 00TP of the thin-film transistor 00T on the first substrate 101 may be designed to be U-shaped, the positions of the first via K1, the channel region of the thin-film transistor 00T, and the second via K2 in the direction parallel to the plane where the display panel 000 is located may be relatively concentrated, that is, the space occupied by the entire thin-film transistor 00T may be relatively small, so the first light-shielding member 1051, the second light- shielding member 1052, and the third light-shielding member 1053 may be set as a whole for light shielding, which may be conducive to simplifying the process steps, reducing the difficulty of the process, and improving the process efficiency.

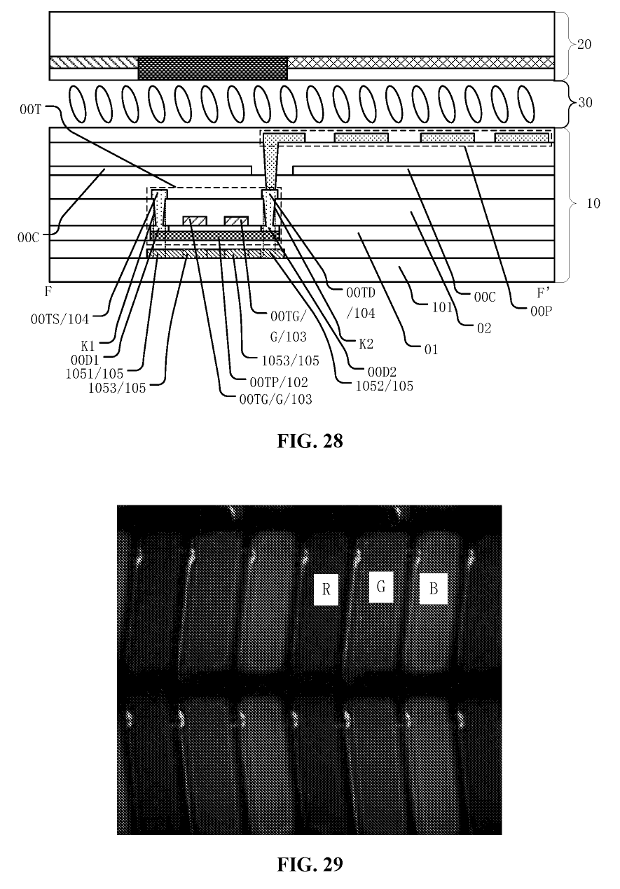

FIG. 27 is another cross-sectional structural schematic diagram along the C-C' direction in FIG. 18, and FIG. 28 is another cross-sectional structural schematic diagram along the F-F' direction in FIG. 25. As shown in FIGS. 1-5, FIG. 18, FIG. 20-26, FIG. 27 and FIG. 28, in one embodiment, the display panel 000 may also include a first conductive portion 00D1, which may be in direct contact with the active part 00TP of the thin-film transistor 00T in the first via hole Kl. In another embodiment, the display panel 000 may also include a second conductive portion 00D2 made of the same material as the first conductive portion 00D1, and the second conductive portion 00D2 may be in direct contact with the active part 00TP of the thin- film transistor 00T in the second via hole K2.

This embodiment explains that the first terminal 00TS of the thin-film transistor 00T may be electrically connected to the active part 00TP of the thin-film transistor 00T (the source connection area of the active part 00TP) through the first via hole K1, and the second terminal 00TD of the thin-film transistor 00T may be electrically connected to the active part 00TP of the thin-film transistor 00T (the drain connection area of the active part 00TP) through the second via hole K2. To avoid the fact that the contact area between the first terminal 00TS of the thin-film transistor 00T and the active part 00TP of the thin-film transistor 00T in the first via hole K1 is too small due to the process of the first via hole K1 and the second via hole K2, resulting in poor electrical performance transmission, and the contact area between the second terminal 00TD of the thin-film transistor 00T and the active part 00TP of the thin-film transistor 00T in the second via hole K2 is too small, resulting in poor electrical performance transmission. This embodiment may arrange the display panel 000 to further include a first conductive portion 00D1, and the first conductive portion 00D1 may be in direct contact with the active part 00TP of the thin-film transistor 00T in the first via hole Kl. In some embodiments, the display panel 000 may further include a second conductive portion 00D2 made of the same material as the first conductive portion 00D1, and the second conductive portion 00D2 may directly contact the active portion 00TP of the thin-film transistor 00T in the second via hole K2. Along the first direction X, the first conductive portion 00D1 may be slightly wider than the width of the data line S, and the width of the second conductive portion 00D2 may be slightly wider than the width of the second via hole K2 in the first direction X. By providing the first conductive portion 00D1 and the second conductive portion 00D2, the contact area between the first terminal 00TS and the second terminal 00TD of the thin-film transistor 00T and the active part 00TP of the thin-film transistor 00T may be increased, thereby ensuring the charging performance of the thin- film transistor 00T, which may be conducive to improving the product yield.

It can be understood that the first conductive portion 00D1 and the second conductive portion 00D2 of this embodiment may be set according to the charging requirements of the display panel 000 itself. The shape of the orthographic projection of the active part 00TP of the thin-film transistor 00T on the first substrate 101 may be L-shaped or U-shaped as a whole, and the first conductive portion 00D1 and the second conductive portion 00D2 may be set. The first conductive portion 00D1 and the second conductive portion 00D2 may be made of the same metal material as the data line S. The manufacturing process thereof is not described in detail in this embodiment and the details may be referred to the manufacturing process of the panel in the relevant technology.

In some embodiments, as shown in FIGS. 27-28, at the first via K1, the orthographic projection of the first via K1 on the first substrate 101 may be located within the orthographic projection range of the first conductive portion 00D1 on the first substrate 101, and the orthographic projection of the first conductive portion 00D1 on the first substrate 101 may be located within the orthographic projection range of the first light-shielding member 1051 on the first substrate 101.

In one embodiment, the first via hole K1 may be arranged, and the orthographic projection of the first via hole K1 on the first substrate 101 may be located within the orthographic projection range of the first conductive portion 00D1 on the first substrate 101, that is, the orthographic projection of the first conductive portion 00D1 on the first substrate 101 may at least cover the orthographic projection position of the first via hole K1 on the first substrate 101, and the orthographic projection area of the first conductive portion 00D1 on the first substrate 101 may be relatively large, and it may be in direct contact with the active part 00TP of the thin-film transistor 00T, so that a good contact conductivity may be guaranteed. The orthographic projection of the first conductive portion 00D1 on the first substrate 101 may be located within the orthographic projection range of the first light-shielding member 1051 on the first substrate 101, which may ensure the light-shielding effect of the first light-shielding member 1051 on the first conductive portion 00D1 of the metal material, effectively avoid metal light leakage at the first via hole K1, and better improve the display contrast of the display panel 000. Similarly, at the second via K2, the orthographic projection of the second via K2 on the first substrate 101 may be located within the orthographic projection range of the second conductive portion 00D2 on the first substrate 101, that is, the orthographic projection of the second conductive portion 00D2 on the first substrate 101 may at least cover the orthographic projection position of the second via K2 on the first substrate 101, and the orthographic projection area of the second conductive portion 00D2 on the first substrate 101 may be relatively large, and may be in direct contact with the active part 00TP of the thin-film transistor 00T, so that a good contact conductivity may be guaranteed. The orthographic projection of the second conductive portion 00D2 on the first substrate 101 may be located within the orthographic projection range of the second light-shielding member 1052 on the first substrate 101, which may ensure the light-shielding effect of the second light-shielding member 1052 on the second conductive part 00D2 of the metal material, effectively avoid metal light leakage at the second via K2, and better improve the display contrast of the display panel 000.

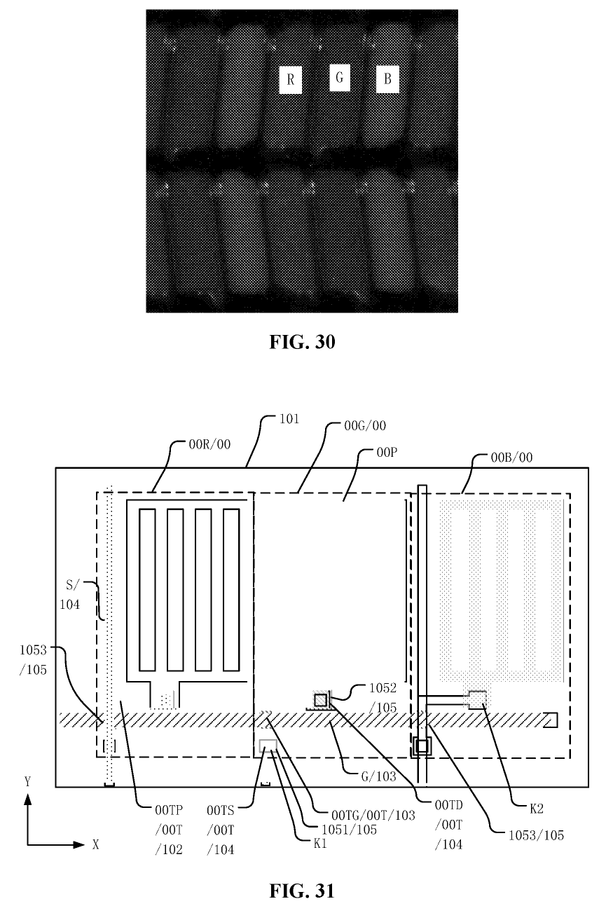

FIG. 29 is a display simulation diagram of a product in a certain project under dark display, and FIG. 30 is a display simulation diagram of a product in another project under dark display. From the simulation diagrams of the dark display shown in FIGS. 29-30, it can be seen that different sub-pixel areas of the display panel have metal light leakage problems at the via holes. In the visible light band, the transmittance of green light is higher than that of red light and blue light. Therefore, from the dark state light leakage diagrams of FIGS. 29-30 of the actual product, it can be seen that compared with the green sub-pixel G, the red sub-pixel R, and the blue sub-pixel B, the green sub-pixel G has the most obvious light leakage, that is, the dark state light leakage of the green sub-pixel G is more deteriorated.

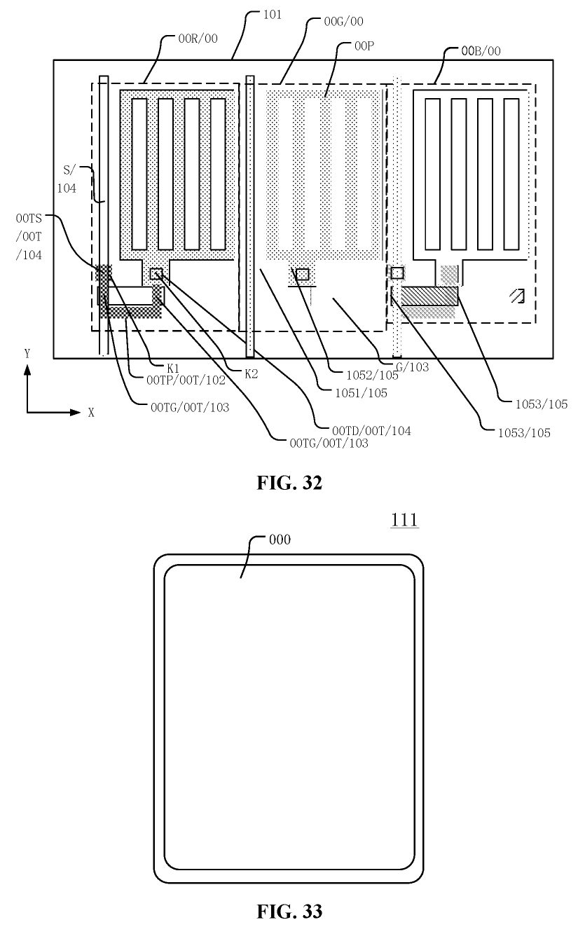

FIG. 31 is another partially enlarged schematic diagram of the J1 region in FIG. 1, and FIG. 32 is another partially enlarged schematic diagram of the J1 region in FIG. 1 (it can be understood that, to clearly illustrate the structure of this embodiment, FIG. 31 and FIG. 32 are filled with transparency). As shown in FIGS. 31-32, to solve the above problem, when the multiple sub-pixels 00 of the display panel 000 include the red sub-pixel 00R, the blue sub-pixel 00B and the green sub-pixel 00G, the area where the green sub-pixel 00G is located may be set to include the first light-shielding member 1051, and the red sub-pixel 00R and the blue sub- pixel 00B region may not include the first light-shielding member 1051, that is, the light leakage problem in the most obvious area may be reduced, and the dark state display effect may be optimized. The red sub-pixel 00R and the blue sub-pixel 00B region may only be provided with the third light-shielding member 1053 corresponding to the channel region of the thin-film transistor 00T, and the corresponding positions of the other vias may not use the structure of the third metal layer 105 for light-shielding, thereby effectively improving the transmittance of the display panel 000 and better balancing the display performance of high contrast and high transmittance.

It can be understood that for the embodiment in which the shape of the orthographic projection of the active part 00TP of the thin-film transistor 00T in the display panel 000 on the first substrate 101 is L-shaped as a whole, a first light-shielding member 1051 of the third metal layer 105 may be provided at the first via hole K1 of the green sub-pixel 00G, a second light-shielding member 1052 of the third metal layer 105 may be provided at the second via hole K2 of the green sub-pixel 00G, a third light-shielding member of the third metal layer 105 may be provided at a position corresponding to the channel region of the thin-film transistor 00T of the green sub-pixel 00G, and a third light-shielding member of the third metal layer 105 may be provided only at a position corresponding to the channel region of the thin-film transistor 00T for the red sub-pixel 00R and the blue sub-pixel 00B, so as to shield the channel region (as shown in FIG. 31). For the embodiment in which the shape of the orthographic projection of the active part 00TP of the thin-film transistor 00T in the display panel 000 on the first substrate 101 is U-shaped as a whole, the first light-shielding member 1051, the second light-shielding member 1052, and the third light-shielding member 1053 may be set in the green sub-pixel 00G area to cover and shield the first via hole K1, the second via hole K2, and the channel area of the thin-film transistor 00T in the green sub-pixel 00G area, while the red sub-pixel 00R and the blue sub-pixel 00B only set the third light-shielding member of the third metal layer 105 at the corresponding position of the channel area of the thin-film transistor 00T, and there may be no need to expand the first light-shielding member and the second light-shielding member, thereby effectively improving the transmittance of the display panel 000 (as shown in FIG. 32).

The present disclosure also provides a display device. FIG. 33 illustrates a schematic diagram of a planar structure of an exemplary display device according to various embodiments of the present disclosure. As shown in FIG. 33, the display device 111 provided in one embodiment may include a display panel 000 provided in the above embodiment of the present disclosure. In the embodiment of FIG. 33, a mobile phone is used as an example to illustrate the display device 111. It can be understood that the display device 111 provided in the embodiment of the present disclosure may be a computer, a television, a car display device, or other display devices 111 with display functions, and the present disclosure does not specifically limit this. The display device 111 provided in the embodiment of the present disclosure may have the beneficial effects of the display panel 000 provided in the embodiment of the present disclosure, and details may be referred to the specific description of the display panel 000 in the above embodiments, and this embodiment will not be repeated here.

The technical solution provided by the embodiments of the present disclosure may have the following advantages.

The display panel of the present disclosure may be provided with a third metal layer between the first substrate and the semiconductor layer, and the third metal layer may include a plurality of first light-shielding members. The first shielding-member may be provided at the first via hole where the metal light leakage is serious under dark display, and the orthographic projection of the first via hole on the first substrate may be the first projection, and the orthographic projection of the first light-shielding member on the first substrate may be the second projection, and the edge of the second projection may half surrounds the edge of the first projection, that is, the second projection may not completely surround the first projection, but only a part of the edge of the second projection may be surrounded by the outer circle of the edge of the first projection, and the other part of the edge of the second projection may be overlapped or barely overlapped with the part of the edge of the first projection. Not only may the first shielding member block the metal light leakage at the first via hole to ensure the light-shielding effect and improve the contrast in the dark state display as much as possible, but also the edge of the second projection formed by the first light-shielding members may be only the edge of the first projection formed by half surrounding the first via hole. Compared with the light-shielding members structure in the prior art, which generally completely covers the via hole and fully surrounds the periphery of the via hole to ensure the light-shielding performance, the present disclosure not only may not need to widen the light-shielding width of the black matrix layer on the counter substrate side, but also does not need to increase the area of the first light-shielding members at the first via hole on a large scale, which may make the opening area of the sub-pixel sacrificed as small as possible, so as to reduce the dark state metal light leakage phenomenon. And because the pixel density in the existing liquid crystal display panel is relatively high, the opening area of a single sub-pixel is relatively small in itself, so the present disclosure may solve the metal light leakage problem at the first via hole by sacrificing the opening area of the sub- pixel with a smaller area as much as possible, so that the sub-pixel in the display panel may still maintain a relatively high aperture ratio, so that it has a better display performance, may take into account the requirements of high penetration rate and high contrast, and improve the overall display effect of the display panel.

It should be noted that, in this disclosure, relational terms such as "first" and "second" are only used to distinguish one entity or operation from another entity or operation, and do not necessarily require or imply any such actual relationship or order between these entities or operations. Moreover, the terms "include", "comprise" or any other variant thereof are intended to cover non-exclusive inclusion, so that a process, method, article or device including a series of elements includes not only those elements, but also other elements not explicitly listed, or also includes elements inherent to such a process, method, article or device. In the absence of further restrictions, an element defined by the sentence "comprising a ..." does not exclude the presence of other identical elements in the process, method, article or device comprising the element.

The above is only a specific implementation of the present disclosure, so that those skilled in the art can understand or implement the present disclosure. Various modifications to these embodiments will be obvious to those skilled in the art, and the general principles defined herein can be implemented in other embodiments without departing from the spirit or scope of the present disclosure. Therefore, the present disclosure will not be limited to the embodiments described herein, but will conform to the widest scope consistent with the principles and novel features disclosed herein.

What is claimed is:

1. A display panel, comprising:an array substrate and a counter substrate arranged oppositely;a plurality of sub-pixels;a plurality of scan lines; and a plurality of data lines,wherein:the array substrate includes a first substrate, and a semiconductor layer, a first metal layer and a second metal layer located on a side of the first substrate facing the counter substrate;the plurality of scan lines and the plurality of data lines are cross-insulated to define area where the plurality of sub-pixels are located;a sub-pixel of the plurality of sub-pixels includes a thin-film transistor and a pixel electrode that are electrically connected, the plurality of scan lines are located in the first metal layer, an active part of the thin-film transistor is located in the semiconductor layer, and a first terminal and a second terminal of the thin-film transistor and the plurality of data lines are located in the second metal layer;the active part of the thin-film transistor is electrically connected to the first terminal of the thin-film transistor through a first via hole, the first terminal of the thin-film transistor is electrically connected to a data line of the plurality of data lines, and the second terminal of the thin-film transistor is electrically connected to the pixel electrode;
a third metal layer is also included between the first substrate and the semiconductor layer, the third metal layer includes a plurality of first light-shielding members and, at the first via hole, an orthographic projection of the first via hole on the first substrate is at least within an orthographic projection range of a first light-shielding member of the plurality of light-shielding member on the first substrate; and
the orthographic projection of the first via hole on the first substrate is a first projection, the orthographic projection of the first light-shielding member on the first substrate is a second projection, and an edge of the second projection half surrounds an edge of the first projection.

2. The display panel according to claim 1, wherein:along an extension direction of a scan line of the plurality of scan lines, the first projection includes a first edge and a second edge opposite to each other, the first edge faces the second terminal of the thin-film transistor, and the second edge is located at a side of the first edge away from the second terminal of the thin-film transistor, the second projection includes a third edge and a fourth edge opposite to each other, the third edge faces the second terminal of the thin-film transistor, and the fourth edge is located at a side of the third edge away from the second terminal of the thin-film transistor; and a maximum distance between the first edge and the second edge is D1, a minimum distance between the third edge and the fourth edge is D2, and D2>D1.

3. The display panel according to claim 2, wherein:
the third edge is located at a side of the first edge away from the second edge; and
the fourth edge is flush with the second edge.

4. The display panel according to claim 2, wherein:the fourth edge is located at a side of the second edge away from the first edge; and the third edge is flush with the first edge.

5. The display panel according to claim 2, wherein:the third edge is located at a side of the first edge away from the second edge; and the fourth edge is located at a side of the second edge away from the first edge.

6. The display panel according to claim 2, wherein:along the extension direction of the scan line, a minimum distance that the third edge exceeds an edge of the data line is 2-2.2pm.

7. The display panel according to claim 2, further comprising:a black matrix layer including a plurality of first light-shielding strips and a plurality of second light-shielding strips in a same layer,wherein:the plurality first light-shielding strips and the plurality of second light-shielding strips are cross-arranged to form a mesh structure, and an extension direction of a first light-shielding
strip of the plurality of first light-shielding strips is same as the extension direction of the data line; andthe first light-shielding strip includes a first protrusion, and an orthographic projection of the first light-shielding strip on the first substrate is located within an orthographic projection range of the first protrusion on the first substrate.

8. The display panel according to claim 7, wherein:the orthographic projection of the first light-shielding member on the first substrate coincides with the orthographic projection of the first protruding portion on the first substrate.

9. The display panel according to claim 2, wherein:an orthographic projection of the active part of the thin-film transistor on the first substrate is L-shaped.

10. The display panel according to claim 9, wherein:the active part of the thin-film transistor is electrically connected to the second terminal of the thin-film transistor through a second via hole;the third metal layer also includes a plurality of second light-shielding members and a plurality of third light-shielding members;
at the second via hole, an orthographic projection of the second via hole on the first substrate is at least located within an orthographic projection range of a second light-shielding member of the plurality of second light-shielding members on the first substrate;
an orthographic projection of a third light-shielding member of the plurality of third light- shielding members on the first substrate covers an orthographic projection of a channel region of the thin-film transistor on the first substrate; and
the first light-shielding member, the second light-shielding member and the third light- shielding member are independent structures.

11. The display panel according to claim 1, wherein:an orthographic projection of the active part of the thin-film transistor on the first substrate is U-shaped.

12. The display panel according to claim 11, wherein:the third metal layer also includes a plurality of second light-shielding members;the active part of the thin-film transistor is electrically connected to the second terminal of the thin-film transistor through a second via hole, and an orthographic projection of the second via hole on the first substrate is located within an orthographic projection range of a second light- shielding member of the plurality of second light-shielding members on the first substrate;
the orthographic projection of the second via hole on the first substrate is a third projection, and the orthographic projection of the second light-shielding member on the first substrate is a fourth projection;
along the extension direction of the scan line, the first projection includes a fifth edge away from the third projection, the third projection includes a sixth edge away from the first projection, the second projection includes a seventh edge away from the fourth projection, and the fourth projection includes an eighth edge away from the second projection; and
a maximum distance between the fifth edge and the sixth edge is D3, a minimum distance between the seventh edge and the eighth edge is D4, and D4>D3.

13. The display panel according to claim 12, wherein:D4-D3<1pm.

14. The display panel according to claim 12, wherein:the third metal layer also includes a plurality of third light-shielding members; and an orthographic projection of a channel region of the thin-film transistor on the first substrate is located within an orthographic projection range of a third light-shielding member of the plurality of third light-shielding members on the first substrate.

15. The display panel according to claim 14, wherein:
the first light-shielding member, the second light-shielding member and the third light- shielding member are independent structures respectively.

16. The display panel according to claim 14, wherein the first light-shielding member, the second light-shielding member and the third light- shielding member are an integrated structure.

17. The display panel according to claim 1, further comprising:a first conductive portion directly contacted the active part of the thin-film transistor in the first via hole.

18. The display panel according to claim 17, wherein:at the first via hole, an orthographic projection of the first via hole on the first substrate is located within an orthographic projection range of the first conductive portion on the first substrate, and an orthographic projection of the first conductive portion on the first substrate is located within an orthographic projection range of a first light-shielding member of the plurality of light-shielding members on the first substrate.

19. The display panel according to claim 1, wherein:the plurality of sub-pixels include red sub-pixels, blue sub-pixels and green sub-pixels;
and
a region where a green sub-pixel is located includes a first-light shielding member of the plurality of light-shielding members, and regions where the red sub-pixels and the blue sub- pixels are located do not include the first light-shielding member.

20. A display device, comprising:a display panel, including:an array substrate and a counter substrate arranged oppositely;a plurality of sub-pixels;a plurality of scan lines; and a plurality of data lines,wherein:the array substrate includes a first substrate, and a semiconductor layer, a first metal layer and a second metal layer located on a side of the first substrate facing the counter substrate;the plurality of scan lines and the plurality of data lines are cross-insulated to define area where the plurality of sub-pixels are located;a sub-pixel of the plurality of sub-pixels includes a thin-film transistor and a pixel electrode that are electrically connected, the plurality of scan lines are located in the first metal layer, an active part of the thin-film transistor is located in the semiconductor layer, a first terminal and a second terminal of the thin-film transistor and the plurality of data lines are located in the second metal layer;
the active part of the thin-film transistor is electrically connected to the first terminal of the thin-film transistor through a first via hole, the first terminal of the thin-film transistor is electrically connected to a data line of the plurality of data lines, and the second terminal of the thin-film transistor is electrically connected to the pixel electrode;
a third metal layer is also included between the first substrate and the semiconductor layer, the third metal layer includes a plurality of first light-shielding members, and, at the first via hole, an orthographic projection of the first via hole on the first substrate is at least within an orthographic projection range of a first light-shielding member of the plurality of light-shielding member on the first substrate; and
the orthographic projection of the first via hole on the first substrate is a first projection, the orthographic projection of the first light-shielding member on the first substrate is a second projection, and an edge of the second projection half surrounds an edge of the first projection.
